(19) United States
(12) Patent Application Publication
(10) Pub. No.: US 2025/0096179 A1
(43) Pub. Date: Mar. 20, 2025

(54) SEMICONDUCTOR PACKAGE

(71) Applicant: Samsung Electronics Co., Ltd., Suwon-si (KR)

(72) Inventors: Wooyoung KIM, Suwon-si (KR); Yeonho JANG, Suwon-si (KR); Kimin CHEONG, Suwon-si (KR)

(73) Assignee: Samsung Electronics Co., Ltd., Suwon-si (KR)

(21) Appl. No.: 18/754,738

(22) Filed: Jun. 26, 2024

(30) Foreign Application Priority Data
Sep. 14, 2023 (KR) 10-2023-0122667

(51) Int. Cl. H01L 23/00; H01L 23/31; H01L 23/49; H01L 23/498; H01L 23/552; H01L 25/10

(52) U.S. Cl. CPC H01L 24/20; H01L 23/3107; H01L 23/49; H01L 23/49822; H01L 23/552; H01L 23/562; H01L 24/24; H01L 23/49816; H01L 24/16; H01L 24/32; H01L 24/73; H01L 25/105; H01L 2224/16227; H01L 2224/215; H01L 2224/24221; H01L 2224/32225; H01L 2224/73204; H01L 2225/1011; H01L 2924/16787

(57) ABSTRACT

A semiconductor package may include a first wiring structure including a plurality of first redistribution patterns and a plurality of first redistribution insulating layers, a second wiring structure on the first wiring structure and including a plurality of second redistribution patterns and a plurality of second redistribution insulating layers, a semiconductor chip between the first wiring structure and the second wiring structure, an expanded layer including a plurality of connection structures electrically connecting the first wiring structure and the second wiring structure to each other and an encapsulant surrounding the plurality of connection structures and the semiconductor chip, a ceramic shield layer between the expanded layer and the second wiring structure, and a plurality of via structures penetrating the ceramic shield layer and electrically connecting the plurality of connection structures and the plurality of second redistribution patterns to each other.

### CROSS-REFERENCE TO RELATED APPLICATION

This application is based on and claims priority under 35 U.S.C. § 119 to Korean Patent Application No. 10-2023-0122667, filed on Sep. 14, 2023, in the Korean Intellectual Property Office, the disclosure of which is incorporated by reference herein in its entirety.

### BACKGROUND

Inventive concepts relate to a semiconductor package, and more particularly, to a fan-out semiconductor package.

With the rapid development of the electronics industry and user demands, electronic devices are becoming more compact, multi-functional, and higher capacity, and accordingly, highly integrated semiconductor chips may be required.

Therefore, for highly integrated semiconductor chips with an increased number of connection terminals for input/output (I/O), semiconductor packages having connection terminals with guaranteed connection reliability are being designed. For example, in order to limit and/or prevent interference between connection terminals, a fan-out semiconductor package with an increased spacing between connection terminals has been developed.

### SUMMARY

Inventive concepts provide a semiconductor package with improved structural and/or operational reliability.

According to an embodiment of inventive concepts, a semiconductor package may include a first wiring structure including a plurality of first redistribution patterns and a plurality of first redistribution insulating layers surrounding the plurality of first redistribution patterns; a second wiring structure on the first wiring structure, the second wiring structure including a plurality of second redistribution patterns and a plurality of second redistribution insulating layers surrounding the plurality of second redistribution patterns; a semiconductor chip between the first wiring structure and the second wiring structure; an expanded layer including a plurality of connection structures electrically connecting the first wiring structure and the second wiring structure to each other and an encapsulant surrounding the plurality of connection structures and the semiconductor chip; a ceramic shield layer between the expanded layer and the second wiring structure; and a plurality of via structures penetrating the ceramic shield layer and electrically connecting the plurality of connection structures and the plurality of second redistribution patterns to each other.

According to an embodiment of inventive concepts, a semiconductor package may include a first wiring structure including a plurality of first redistribution insulating layers and a plurality of first redistribution patterns, the plurality of first redistribution patterns including a plurality of first redistribution line patterns and a plurality of first redistribution vias, the plurality of first redistribution line patterns on at least one of upper surfaces and lower surfaces of the plurality of first redistribution insulating layers, and the plurality of first redistribution vias being connected to the plurality of first redistribution line patterns and penetrating at least one of the plurality of first redistribution insulating layers; a plurality of connection structures on the first wiring structure and connected to some first redistribution patterns among the plurality of first redistribution patterns; a semiconductor chip spaced apart from the plurality of connection structures in a horizontal direction on the first wiring structure and electrically connected to other first redistribution patterns among the plurality of first redistribution patterns; an encapsulant surrounding the plurality of connection structures and the semiconductor chip on the first wiring structure; a ceramic shield layer covering the encapsulant and having a plurality of through holes; a plurality of via structures filing the plurality of through holes of the ceramic shield layer, the plurality of via structures being connected to and in contact with the plurality of connection structures; and a second wiring structure on the ceramic shield layer. The second wiring structure may include a plurality of second redistribution insulating layers and a plurality of second redistribution patterns. The plurality of second redistribution patterns may include a plurality of second redistribution line patterns and a plurality of second redistribution vias. The plurality of second redistribution line patterns may be on at least one of upper surfaces and lower surfaces of the plurality of second redistribution insulating layers. The plurality of second redistribution vias may be connected to the plurality of second redistribution line patterns and penetrating at least one of the plurality of second redistribution insulating layers. Lowest second redistribution vias among the plurality of second redistribution vias may be connected to and in contact with the plurality of pad patterns.

According to an embodiment of inventive concepts, a semiconductor package may include a lower package including a first wiring structure, a second wiring structure on the first wiring structure, a semiconductor chip between the first wiring structure and the second wiring structure, a plurality of connection structures electrically connecting the first wiring structure and the second wiring structure to each other, an encapsulant covering a side surface of the semiconductor chip and an upper surface of the semiconductor chip, a ceramic shield layer between the encapsulant and the second wiring structure, and a plurality of via structures penetrating the ceramic shield layer, the first wiring structure including a plurality of first redistribution patterns and a plurality of first redistribution insulating layers surrounding the plurality of first redistribution patterns, the second wiring structure including a plurality of second redistribution patterns and a plurality of second redistribution insulating layers surrounding the plurality of second redistribution patterns, the plurality of connection structures being spaced apart from the semiconductor chip in a horizontal direction and disposed around the semiconductor chip, the encapsulant surrounding the plurality of connection structures, and the plurality of via structures electrically connecting the plurality of connection structures and the plurality of second redistribution patterns to each other; an upper package attached to the lower package and including an auxiliary semiconductor chip; and a plurality of package connection terminals between the lower package and the upper package, the plurality of package connection terminals electrically connecting the lower package and the upper package to each other. An upper surface of the encapsulant and an uppermost surface of the plurality of connection structures may be located at a same vertical level and may form a coplanar surface. A lower surface of the ceramic shield layer may be a flat surface in contact with the upper surface of the encapsulant and the uppermost surface of the plurality of connection structures.

### BRIEF DESCRIPTION OF THE DRAWINGS

Embodiments of inventive concepts will be more clearly understood from the following detailed description taken in conjunction with the accompanying drawings in which:

FIG. 1 is a cross-sectional view of a semiconductor package according to an embodiment;

FIGS. 2A to 2K are cross-sectional views showing a method of manufacturing a semiconductor package, according to embodiments;

FIGS. 3 to 6 are cross-sectional views of semiconductor packages according to embodiments;

FIG. 7 is a cross-sectional view of a semiconductor package according to an embodiment;

FIGS. 8A to 8H are cross-sectional views showing a method of manufacturing a semiconductor package, according to embodiments;

FIG. 9 is a cross-sectional view of a semiconductor package according to an embodiment; and

FIGS. 10 and 11 are cross-sectional views of a semiconductor package according to an embodiment.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”, “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

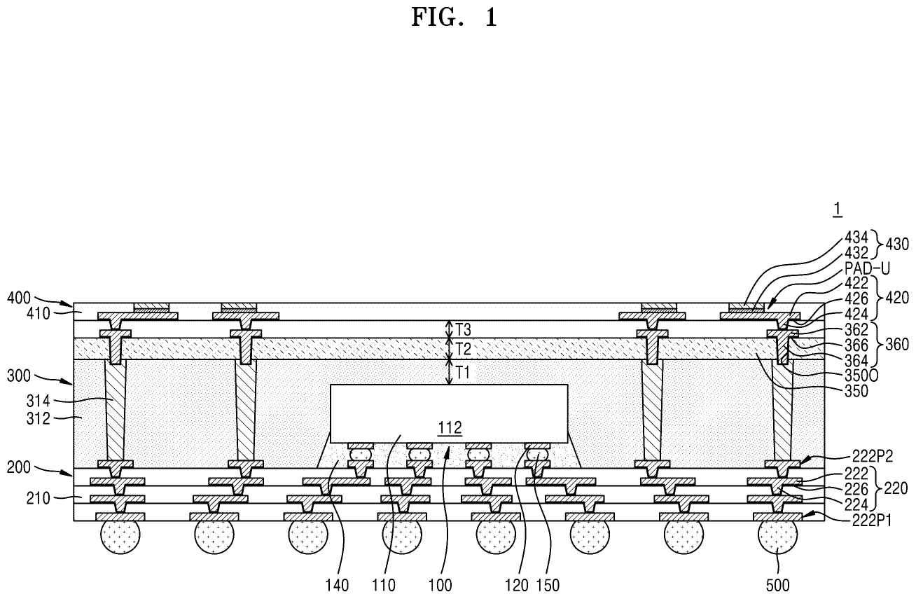

FIG. 1 is a cross-sectional view of a semiconductor package according to an embodiment.

Referring to FIG. 1, a semiconductor package 1 may include a first wiring structure 200, a second wiring structure 400 on the first wiring structure 200, at least one semiconductor chip 100 disposed between the first wiring structure 200 and the second wiring structure 400, an expanded layer 300 between the first wiring structure 200 and the second wiring structure 400 and surrounding the at least one semiconductor chip 100, and a ceramic shield layer 350 between the expanded layer 300 and the second wiring structure 400. The expanded layer 300 may electrically connect the first wiring structure 200 and the second wiring structure 400 to each other. In some embodiments, the semiconductor package 1 may be a lower package of a package-on-package (POP). The semiconductor package 1 may be a fan out type semiconductor package in which the horizontal width and horizontal area of the first wiring structure 200 are greater than the horizontal width and horizontal area of the footprint of at least one semiconductor chip 100. In some embodiments, the semiconductor package 1 may be a fan out type wafer level package (FOWLP).

In some embodiments, at least one of the first wiring structure 200 and the second wiring structure 400 may be formed through a redistribution process. Each of the first wiring structure 200 and the second wiring structure 400 may be referred to as a first redistribution structure and a second redistribution structure, or may be referred to as a lower redistribution structure and an upper redistribution structure. In some embodiments, the semiconductor package 1 may be formed in a chip last manner by forming the first redistribution structure 200 and then forming at least one semiconductor chip 100 and the expanded layer 300 on the first redistribution structure 200. In some other embodiments, at least one of the first wiring structure 200 and the second wiring structure 400 may be a printed circuit board. For example, the first wiring structure 200 is a printed circuit board, and the second wiring structure 400 may be a redistribution structure formed through a redistribution process.

The first wiring structure 200 may include a first redistribution insulating layer 210 and a plurality of first redistribution patterns 220. The first redistribution insulating layer 210 may surround the plurality of first redistribution patterns 220. In some embodiments, the first wiring structure 200 may include a plurality of first redistribution insulating layers 210 that are stacked. The first redistribution insulating layer 210 may include an organic material. For example, the first redistribution insulating layer 210 may be formed from photo imageable dielectric (PID) or photosensitive polyimide (PSPI). The first redistribution insulating layer 210 may have a first thickness T1. For example, the first thickness T1 may be about 20 μm to about 40 μm.

The plurality of first redistribution patterns 220 may include a plurality of first redistribution line patterns 222, a plurality of first redistribution vias 224, and a plurality of first redistribution seed layers 226. The plurality of first redistribution patterns 220 may be, for example, a metal or metal alloy such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), Rhenium (Re), beryllium (Be), gallium (Ga), ruthenium (Ru), etc., but are not limited thereto. In some embodiments, the first redistribution line pattern 222 and the first redistribution via 224 may be made of the same material, and the first redistribution seed layer 226 may be made of a different material from each of the first redistribution line pattern 222 and the first redistribution via 224. In some embodiments, the first redistribution line pattern 222 and the first redistribution via 224 may include copper. For example, the first redistribution line pattern 222 and the first redistribution via 224 may be made of copper or a copper alloy. In some embodiments, the first redistribution seed layer 226 may include titanium. For example, the first redistribution seed layer 226 may be made of titanium or titanium nitride.

The plurality of first redistribution line patterns 222 may be disposed on at least one of the upper and lower surfaces of the first redistribution insulating layer 210. For example, when the first wiring structure 200 includes a plurality of stacked first redistribution insulating layers 210, a plurality of first redistribution line patterns 222 may be disposed on the lower surface of each of the plurality of first redistribution insulating layers 210.

The plurality of first redistribution vias 224 may penetrate through at least one first redistribution insulating layer 210 and may each be in contact with and connected to some of the plurality of first redistribution line patterns 222. In some embodiments, the plurality of first redistribution vias 224 may have a tapered shape that extends and becomes wider in horizontal width from the bottom to the top. For example, the horizontal width of the plurality of first redistribution vias 224 may increase as the plurality of first redistribution vias 224 approach at least one semiconductor chip.

In some embodiments, at least some of the plurality of first redistribution line patterns 222 may be formed together with some of the plurality of first redistribution vias 224 to form an integrated unit. For example, the first redistribution line pattern 222 and the first redistribution via 224 in contact with the lower surface of the first redistribution line pattern 222, that is, the first redistribution via 224 extending from the lower surface of the first redistribution line pattern 222, may be formed together to form an integrated unit. For example, the horizontal width of each of the plurality of first redistribution vias 224 may become narrow as it moves away from the integrated first redistribution line pattern 222. The first redistribution seed layer 226 may cover the lower portion of the first redistribution line pattern 222 and the first redistribution via 224 that are integrated with each other. For example, the first redistribution seed layer 226 may cover the lower surface of the first redistribution line pattern 222 and the side and lower surfaces of the first redistribution via 224, among the surfaces of the first redistribution line pattern 222 and the first redistribution via 224, which are integrated with each other. The first redistribution seed layer 226 may not cover the side and upper surfaces of the first redistribution line pattern 222.

In some embodiments, the lower surface of the lowermost first redistribution insulating layer 210 and the lowermost surface of the plurality of first redistribution patterns 220, for example, the lower surface of the lowermost first redistribution line pattern 222 may be located at the same vertical level and form a coplanar surface.

The first wiring structure 200 may include a plurality of lower surface connection pads 222P1 disposed on a lower surface of the first wiring structure 200 and a plurality of expansion connection pads 222P2 disposed on an upper surface of the first wiring structure 200. In some embodiments, the plurality of bottom connection pads 222P1 and the plurality of expansion connection pads 222P2 may be some of the plurality of first redistribution line patterns 222. In some embodiments, the lower surface of the plurality of lower surface connection pads 222P1 and the lower surface of the lowermost first redistribution insulating layer 210 may be at the same vertical level and form a coplanar surface. In some embodiments, the plurality of expansion connection pads 222P2 may protrude from the upper surface of the uppermost first redistribution insulating layer 210, so that the upper surface of the plurality of expansion connection pads 222P2 may be at a vertical level higher than the upper surface of the uppermost first redistribution insulating layer 210.

A plurality of external connection terminals 500 may be attached to the plurality of bottom connection pads 222P1. The plurality of external connection terminals 500 may connect the semiconductor package 1 to the outside. For example, each of the plurality of external connection terminals 500 may be a solder ball or a bump. A plurality of connection structures 314 may be attached to some of the plurality of expansion connection pads 222P2, and a plurality of chip connection members 150 may be attached to some other of the expansion connection pads 222P2. For example, each of the plurality of chip connection members 150 may be a solder ball or a micro bump. Each of the plurality of chip connection members 150 may be formed of a conductive material, such as copper (Cu), aluminum (Al), silver (Ag), tin (Tin), gold (Au), or solder, but is not limited thereto. The plurality of chip connection members 150 may be between the plurality of chip pads 120 and other portions of the plurality of expansion connection pads 222P2 to electrically connect at least one semiconductor chip 100 and the first wiring structure 200 to each other. In some embodiments, an underfill layer 140 surrounding the plurality of chip connection members 150 may be between the semiconductor chip 100 and the first wiring structure 200. The underfill layer 140 may be made of, for example, an epoxy resin formed using a capillary under-fill method. In some embodiments, the underfill layer 140 may be a non-conductive film (NCF).

At least one semiconductor chip 100 may be attached to the first wiring structure 200. The semiconductor chip 100 may include a semiconductor substrate 110 having an active surface and an inactive surface, a semiconductor device 112 formed on the active surface of the semiconductor substrate 110, and a plurality of chip pads 120 disposed on the semiconductor device 112. For example, the semiconductor chip 100 may have a thickness of about 70 μm to about 200 μm. The semiconductor chip 100 may have a first surface and a second surface that are opposite to each other. The plurality of chip pads 120 may be disposed on the first surface of the semiconductor chip 100. The second surface of the semiconductor chip 100 may be the inactive surface of the semiconductor substrate 110. Because the active surface of the semiconductor substrate 110 is very close to the first surface of the semiconductor chip 100, illustration in which the active surface of the semiconductor substrate and the first surface of the semiconductor chip are separated is omitted. In FIG. 1, the lower surfaces of the plurality of chip pads 120 and the first surface of the semiconductor chip 100 are shown to be at the same vertical level and form a coplanar surface, but inventive concepts are not limited thereto. For example, the plurality of chip pads 120 may protrude downward from the first surface of the semiconductor chip 100, so that the lower surfaces of the plurality of chip pads 120 may be at a vertical level lower than the first surface of the semiconductor chip 100.

The semiconductor substrate 110 may include a semiconductor material such as silicon (Si) or germanium (Ge). Alternatively, the semiconductor substrate 110 may include a compound semiconductor material such as silicon carbide (SiC), gallium arsenide (GaAs), indium arsenide (InAs), and indium phosphide (InP). The semiconductor substrate 110 may include a conductive region, for example, a well doped with impurities. The semiconductor substrate 110 may have various device isolation structures, such as a shallow trench isolation (STI) structure.

The semiconductor device 112 including a plurality of various types of individual devices may be formed on the active surface of the semiconductor substrate 110. The plurality of individual devices may include various microelectronic devices, such as a metal-oxide-semiconductor field effect transistors (MOSFETs) such as complementary metal-oxide-semiconductor (CMOS) transistors, system large scale integrations (LSIs), active elements (e.g., diodes, transistors), passive elements (e.g., capacitors, resistors, inductors). The plurality of individual devices may be electrically connected to the conductive region of the semiconductor substrate 110. The semiconductor device 112 may further include a conductive wire or a conductive plug that electrically connects at least two of the plurality of individual devices to each other, or the plurality of individual devices to the conductive region of the semiconductor substrate 110. Additionally, each of the plurality of individual devices may be electrically separated from other neighboring individual devices by an insulating film.

In some embodiments, the semiconductor chip 100 may include logic elements. For example, the semiconductor chip 100 may be a central processing unit (CPU) chip, a graphics processing unit (GPU) chip, or an application processor (AP) chip. In some other embodiments, the semiconductor chip 100 may be a memory semiconductor chip including a memory device. For example, the memory device may be a non-volatile memory device, such as flash memory, phase-change random access memory (PRAM), magnetoresistive random access memory (MRAM), ferroelectric random access, memory (FeRAM), or resistive random access memory (RRAM). The flash memory may be, for example, NAND flash memory or V-NAND flash memory. In some embodiments, the memory device may be a volatile memory device, such as dynamic random access memory (DRAM) or static random access memory (SRAM). In some other embodiments, when a semiconductor package 1 includes a plurality of semiconductor chips 100, among the plurality of semiconductor chips 100, at least one may be a central processing unit chip, a graphics processing unit chip, or an application processor chip and at least one other may be a memory semiconductor chip including a memory device.

In some embodiments, at least one semiconductor chip 100 may have a face down arrangement with the first surface facing the first wiring structure 200 and may be attached to the upper surface of the first wiring structure 200. For example, the semiconductor chip 100 may be disposed on the first wiring 200 so that the plurality of chip pads 120 face the first wiring structure 200. In this case, the first surface of the semiconductor chip 100 may be referred to as the lower surface of the semiconductor chip 100, and the second surface of the semiconductor chip 100 may be referred to as the upper surface of the semiconductor chip 100. Unless otherwise specified in this specification, the upper surface refers to the surface facing upward in the drawings, and the lower surface refers to the surface facing downward in the drawings.

The expanded layer 300 may include an encapsulant 312 and a plurality of connection structures 314. The plurality of connection structures 314 may penetrate the encapsulant 312 to electrically connect the first wiring structure 200 and the second wiring structure 400 to each other. The upper surface of the encapsulant 312 and the uppermost surface of the plurality of connection structures 314 may be at the same vertical level and form a coplanar surface.

The plurality of connection structures 314 may include a through mold via (TMV), a conductive post, a conductive pillar, or at least one conductive bump. A plurality of connection structures 314 may be between the first wiring structure 200 and the second wiring structure 400 so as to be spaced apart from the at least one semiconductor chip 100 in the horizontal direction. For example, the plurality of connection structures 314 may be spaced apart from the at least one semiconductor chip 100 in the horizontal direction and may be arranged around the at least one semiconductor chip 100. The plurality of connection structures 314 may be between a plurality of expansion connection pads 222P2 and a plurality of via structures 360. The lower surfaces of the plurality of expansion connection pads 222P2 may be in contact with the plurality of expansion connection pads 222P2 of the first wiring structure 200 and may be electrically connected to the plurality of first redistribution patterns 220, and the upper surfaces of the plurality of expansion connection pads 222P2 may be in contact with the plurality of via structures 360 and may be electrically connected to the plurality of second redistribution patterns 420 through the plurality of via structures 360.

The connection structure 314 may extend in a vertical direction. The horizontal cross-sectional area of the connection structure 314 may have a circular, elliptical, or polygonal horizontal cross-section, and may have a pillar shape extending in the vertical direction. For example, the connection structure 314 may include copper (Cu) or a copper alloy. In some embodiments, the connection structure 314 may extend from the top to the bottom with a horizontal width having a substantially constant value. In some other embodiments, the connection structure 314 may have a tapered shape whose horizontal width narrows and extends from the top to the bottom. For example, the horizontal width of the connection structure 314 may become narrower as the connection structure 314 approaches the first wiring structure 200.

The encapsulant 312 may surround at least one semiconductor chip 100 on the upper surface of the first wiring structure 200. The encapsulant 312 may surround at least one semiconductor chip 100 and a plurality of connection structures 314 and fill a space between the first wiring structure 200 and the second wiring structure 400. The encapsulant 312 may include a polymer material. For example, the encapsulant 312 may be a molding member containing epoxy mold compound (EMC). The encapsulant 312 may contain a filler. For example, the filler may be made of a ceramic-based material that has non-conductive insulating properties. In some embodiments, the filler may include at least one of AlN, BN, Al₂O₃, SiC, and MgO. For example, the filler may be a silica filler or an alumina filler. For example, the encapsulant 312 may include an epoxy-based material containing filler. The average diameter of the filler contained in the encapsulant 312 may be about 3 μm to about 50 μm. The proportion of filler contained in the encapsulant 312 may be about 60 wt % to about 90 wt %.

For example, the encapsulant 312 may have a thickness of about 150 μm to about 300 μm. The encapsulant 312 may cover at least a portion of the side surface and the upper surface of at least one semiconductor chip 100. The encapsulant 312 may have a first thickness T1 on the upper surface of the semiconductor chip 100. For example, the first thickness T1 may be about 20 μm to about 40 μm.

A ceramic shield layer 350 and a plurality of via structures 360 penetrating the ceramic shield layer 350 may be disposed on the expanded layer 300. The ceramic shield layer 350 may have a constant thickness (or a substantially constant thickness) and may cover the encapsulant 312. For example, the lower surface of the ceramic shield layer 350 may be a generally flat surface extending along the same vertical level. For example, the upper surface of the ceramic shield layer 350 may be a generally flat surface extending along the same vertical level. The lower surface of the ceramic shield layer 350 may be at the same vertical level as the upper surface of the encapsulant 314 and the uppermost surface of the plurality of connection structures 314. For example, the lower surface of the ceramic shield layer 350 may contact the upper surface of the encapsulant 312 and the uppermost surface of the plurality of connection structures 314.

The ceramic shield layer 350 may be made of a material that has low electrical conductivity and excellent electromagnetic wave shielding performance. For example, the ceramic shield layer 350 may include MXene, which is carbon or nitrogen bonded to a transition metal, such as Ti₃CN, Sc₂C, Ti₂C, Ti₃C₂, Nb₂C, V₂C, Ta₄C₃, Mo₂TiC₂, Mo₂Ti₂C₃, Cr₂TiC₂, Ti₂N, Mo₂C, Nb₄C₃, Zr₃C₂, Ti₄N₃, V₄C₃, Hf₃C₂, Mo₂N, Cr₂C, Zr₂C, Nb₂C, Hf₂C, V₃C₂, Ta₃C₂, or Ti4C3. Alternatively, for example, the ceramic shield layer 350 may include a ferrite material, such as nickel oxide, zinc oxide, iron oxide, or a ceramic material mixed with manganese oxide, iron oxide, zinc oxide, silicon oxide, etc. in a certain ratio. The ceramic shield layer 350 may have a second thickness T2. In some embodiments, the second thickness T2 may have a value less than the first thickness T1. For example, the second thickness T2 may be about 5 μm to about 10 μm.

The ceramic shield layer 350 may have a plurality of through holes 350O. The plurality of via structures 360 may fill the plurality of through holes 350O. Each of the plurality of via structures 360 may include a pad pattern portion 362, a through via portion 364, and a via seed layer 366.

For example, the via structure 360 may be a metal or an alloy of metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), Ruthenium (Ru), etc., but is not limited thereto. In some embodiments, the pad pattern portion 362 and the through via portion 364 may be made of the same material, and the via seed layer 366 may be made of a different material from each of the pad pattern portion 362 and the through via portion 364. In some embodiments, the pad pattern portion 362 and the through via portion 364 may include copper. For example, the pad pattern portion 362 and the through via portion 364 may be made of copper or a copper alloy. In some embodiments, the via seed layer 366 may include titanium. For example, the via seed layer 366 may be made of titanium or titanium nitride.

The pad pattern portion 362 may be disposed on the upper surface of the ceramic shield layer 350. The through via portion 364 may penetrate the ceramic shield layer 350 from the pad pattern portion 362 and be connected by contacting the connection structure 314. The through via portion 364 may fill the through hole 350O. In some embodiments, the through via portion 364 may have a constant (or a generally constant) horizontal width and may extend from the top to the bottom. For example, the through via portion 364 may have a horizontal width of about 20 μm to about 40 μm. In some other embodiments, the through via portion 364 may have a tapered shape that extends and becomes narrower in horizontal width from the top to the bottom. For example, the horizontal width of the pad pattern portion 362 may become narrower as the pad pattern portion 362 approaches the connection structure 314. In some embodiments, the pad pattern portion 362 and the through via portion 364, which correspond to and are connected to each other, may be formed together to form an integrated unit. For example, the pad pattern portion 362 and the through via portion 364 in contact with the lower surface of the pad pattern portion 362, that is, the through via portion 364 extending from the lower surface of the pad pattern portion 362, may be formed together to form an integrated unit. The via seed layer 366 may cover the lower portion of the pad pattern portion 362 and the through via portion 364 that are integrated with each other. For example, the via seed layer 366 may cover the lower surface of the pad pattern portion 362 and the side and lower surfaces of the through via portion 364, among the surfaces of the pad pattern portion 362 and the through via portion 364 that are integrated with each other. The via seed layer 366 may not cover the side and upper surfaces of the pad pattern portion 362.

In some embodiments, the lower surface of the through via portion 364 may be at a lower vertical level than the lower surface of the ceramic shield layer 350. For example, the through via portion 364 may extend from the lower surface of the pad pattern portion 362 into the connection structure 314 through the through hole 350O. The lower surface of the through via portion 364 and the lower surface of the plurality of via structures 360 may be at a vertical level lower than the uppermost surface of the connection structure 314.

The second wiring structure 400 may include a second redistribution insulating layer 410 and a plurality of second redistribution patterns 420. The plurality of second redistribution patterns 420 may include a plurality of second redistribution line patterns 422, a plurality of second redistribution vias 424, and a plurality of second redistribution seed layers 426. The second redistribution insulating layer 410 and the plurality of second redistribution patterns 420 included in the second wiring structure 400 are the same as (or substantially similar to) the first redistribution insulating layer 210 and the plurality of first redistribution patterns 220 included in the first wiring structure 200, so descriptions already given may be omitted.

In some embodiments, the thickness of the second wiring structure 400 may be thinner than the thickness of the first wiring structure 200. For example, the first wiring structure 200 may have a thickness of about 30 μm to about 50 μm, and the second wiring structure 400 may be thinner than the thickness of the first wiring structure 200 and may have a thickness of about 20 μm to about 40 μm. In some embodiments, the second wiring structure 400 may include a plurality of second redistribution insulating layers 410 that are stacked. For example, the number of stacked second redistribution insulating layers 410 included in the second wiring structure 400 may be less than the number of stacked first redistribution insulating layers 210 included in the first wiring structure 200. The second redistribution insulating layer 410 may have a third thickness T3. In some embodiments, the third thickness T3 may have a value less than the second thickness T2. For example, the third thickness T3 may be about 3 μm to about 7 μm. In some embodiments, the thickness of the first redistribution insulating layer 210 may be the same as (or substantially the same as) the thickness of the second redistribution insulating layer 410. For example, the first redistribution insulating layer 210 may have a third thickness T3.

The plurality of second redistribution vias 424 may pass through at least one second redistribution insulating layer 410 and may be connected to each other in contact with a portion of the plurality of second redistribution line patterns 422. In some embodiments, the plurality of second redistribution vias 424 may have a tapered shape that extends with a horizontal width that increases from the bottom to the top. For example, the horizontal width of the plurality of second redistribution vias 424 may become wider as the distance from the at least one semiconductor chip 100 increases. Among the plurality of second redistribution vias 424, the lowermost second redistribution vias 424 may be connected to the upper surface of the plurality of pad pattern portions 362.

In some embodiments, at least some of the plurality of second redistribution line patterns 422 may be formed together with some of the plurality of second redistribution vias 424 to form an integrated unit. For example, the second redistribution line pattern 422 and the second redistribution via 424 in contact with the lower surface of the second redistribution line pattern 422, that is, the second redistribution via 424 extending from the lower surface of the second redistribution line pattern 422, may be formed together to form an integrated unit. For example, the horizontal width of each of the plurality of second redistribution vias 424 may become narrow as each of the plurality of second redistribution vias 424 moves away from the integrated second redistribution line pattern 422.

Among an acute angle formed between the side surface of the first redistribution via 224 and the horizontal plane, an acute angle formed between the side surface of the second redistribution via 424 and the horizontal plane, an acute angle formed between the side surface of the through via portion 364 and the horizontal plane, and an acute angle formed between the side surface of the connection structure 314 and the horizontal plane, some may be different from others. For example, the acute angle formed between the side surface of the through via portion 364 and the horizontal plane may have a value greater than each of the acute angle formed between the side surface of the first redistribution via 224 and the horizontal plane and the acute angle formed between the side surface of the second redistribution via 424 and the horizontal plane. In some embodiments, the acute angle formed between the side surface of the through via portion 364 and the horizontal plane may be greater than about 85 degrees, and the acute angle formed between the side surface of the first redistribution via 224 and the horizontal plane and the acute angle formed between the side surface of the second redistribution via 424 and the horizontal plane may each be about 70 degrees to about 80 degrees. For example, the acute angle formed between the side surface of the connection structure 314 and the horizontal plane may have a value greater than each of the acute angle formed by the side surface of the first redistribution via 222 and the horizontal plane and the acute angle formed by the side surface of the second redistribution via 424 and the horizontal plane. In some embodiments, the acute angle formed between the side surface of the through via portion 364 and the horizontal plane may be greater than the acute angle formed between the side surface of the connection structure 314 and the horizontal plane. Alternatively, in some embodiments, the acute angle formed between the side surface of the through via portion 364 and the horizontal plane may be the same as (or substantially the same as) the acute angle formed between the side surface of the connection structure 314 and the horizontal plane. For example, the horizontal surface may be a lower surface of the lowermost first redistribution insulating layer 210, a lower surface of the ceramic shield layer 350, or a lower surface of the lowermost second redistribution insulating layer 410.

The second wiring structure 400 may include a plurality of upper surface connection pads PAD-U disposed on the upper surface of the second wiring structure 400. In some embodiments, each of the plurality of upper surface connection pads PAD-U may include a portion of the second redistribution line pattern 422 and an upper surface connection pad layer 430 covering an upper surface of the portion of the second redistribution line pattern 422. The upper surface connection pad layer 430 may include a first upper surface metal layer 432 and a second upper surface metal layer 434 sequentially stacked on the second redistribution line pattern 422. In some embodiments, the first upper surface metal layer 432 may include nickel (Ni), and the second upper surface metal layer 434 may include gold (Au), but are not limited thereto.

The semiconductor package 1 may include a ceramic shield layer 350 between at least one semiconductor chip 100 and the second wiring structure 400. The ceramic shield layer 350 may shield electromagnetic waves that may be generated from at least one semiconductor chip 100. The ceramic shield layer 350 may have relatively higher stiffness and relatively higher heat generation characteristics than at least some of the first wiring structure 200, the second wiring structure 400, and the encapsulant 312. Accordingly, the semiconductor package 1 according to inventive concepts may have improved electromagnetic wave characteristics and improved heat generation characteristics, which may limit and/or minimize the occurrence of warping, thereby improving structural reliability and operational reliability.

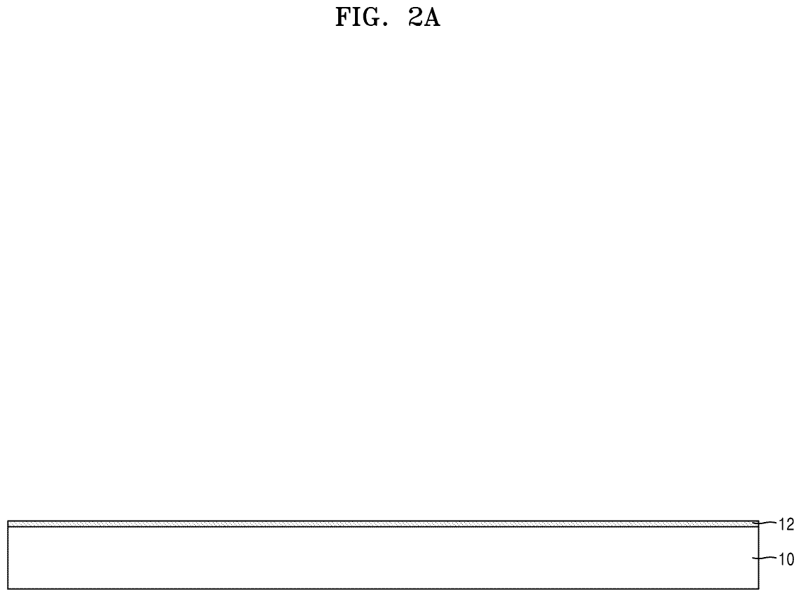

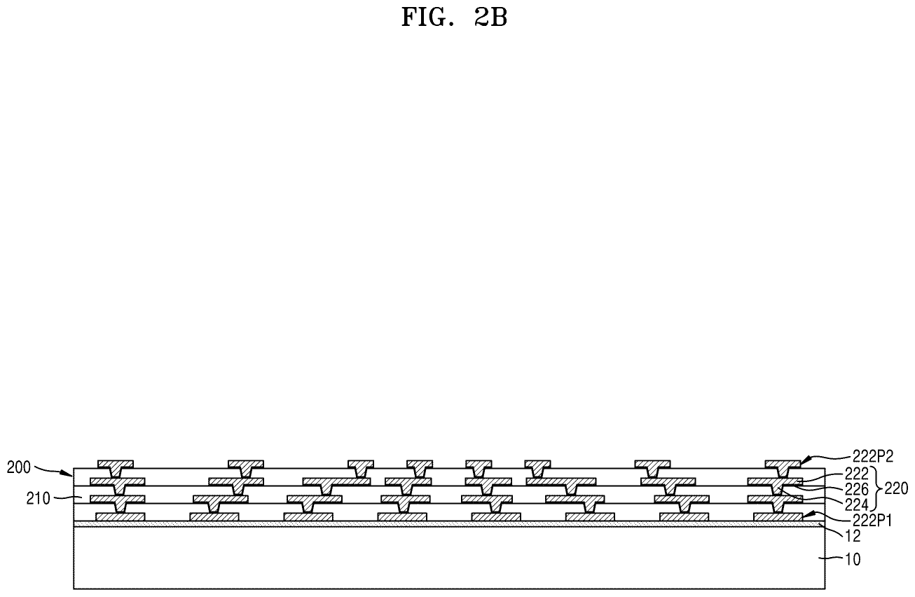

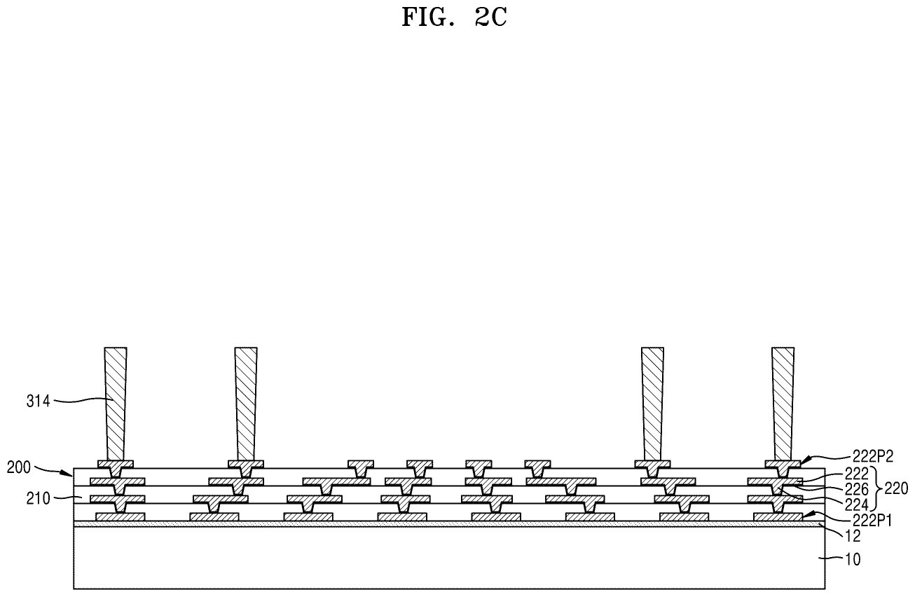

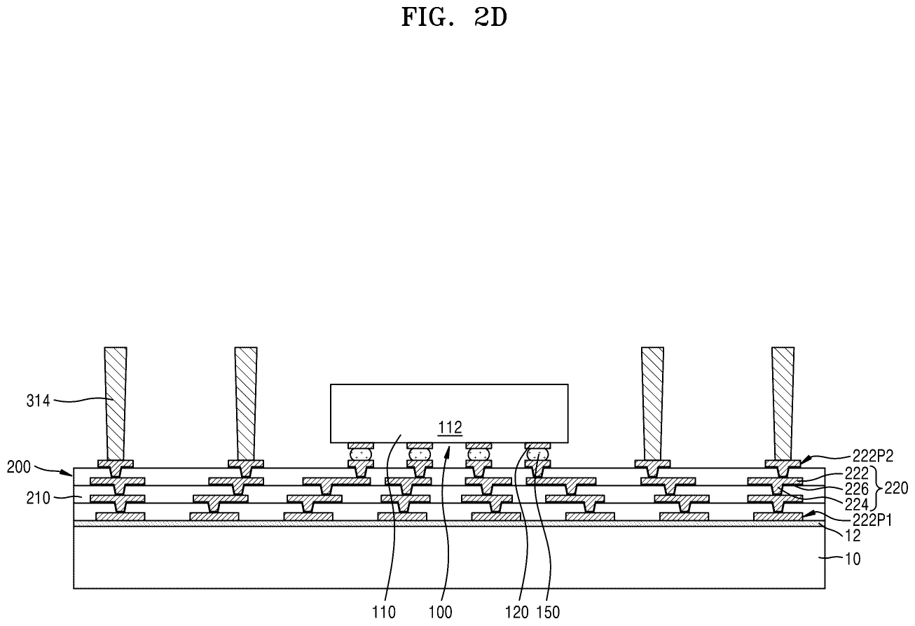

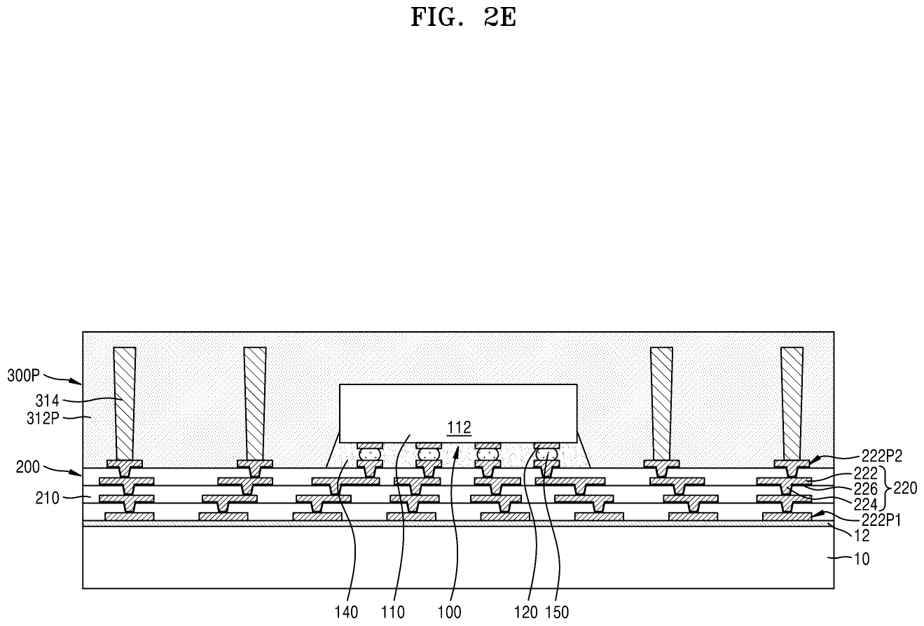

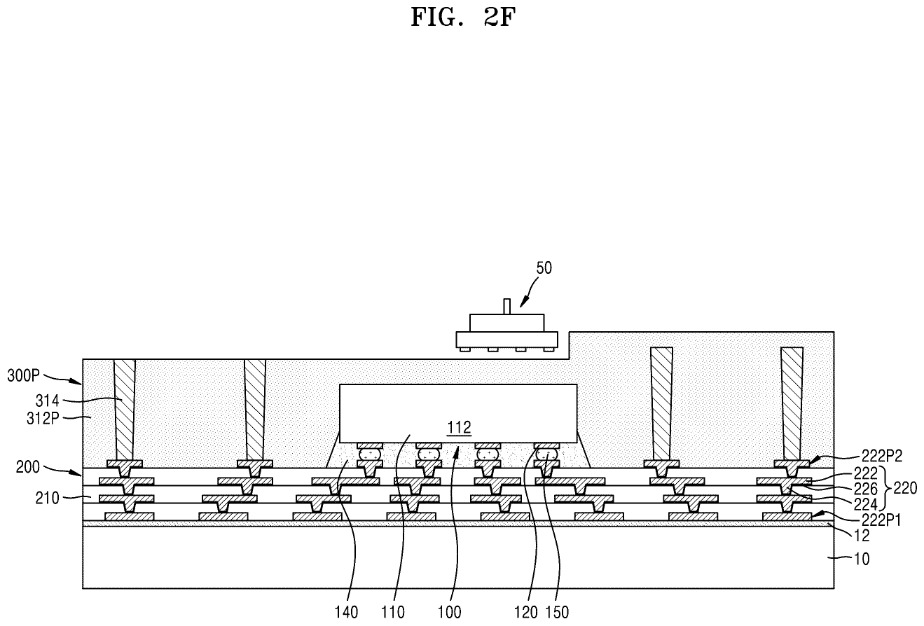

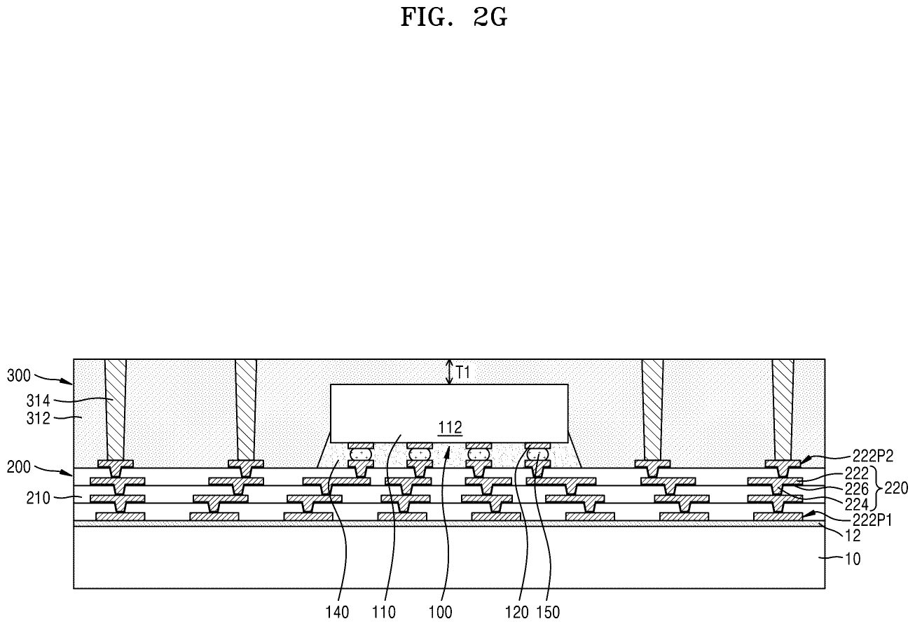

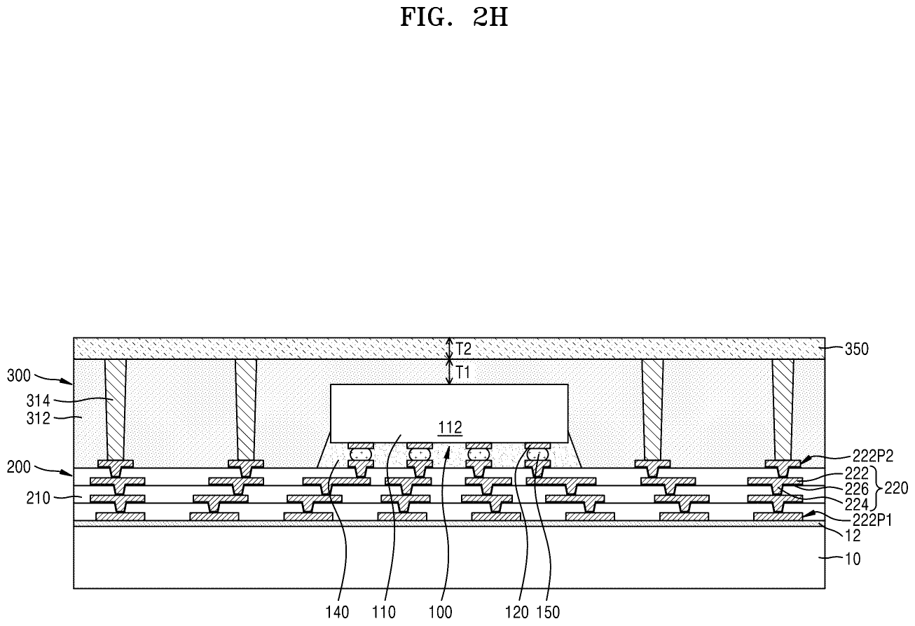

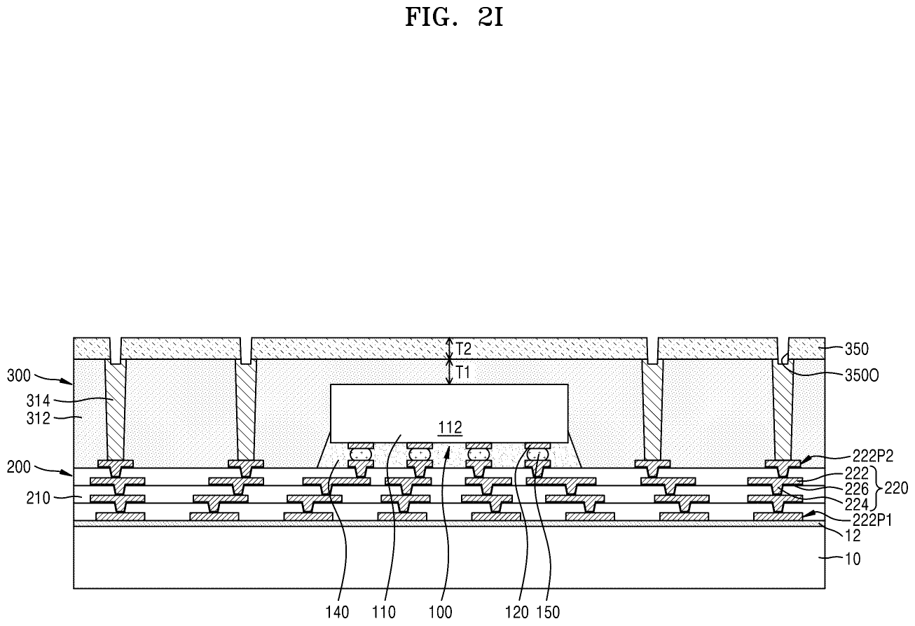

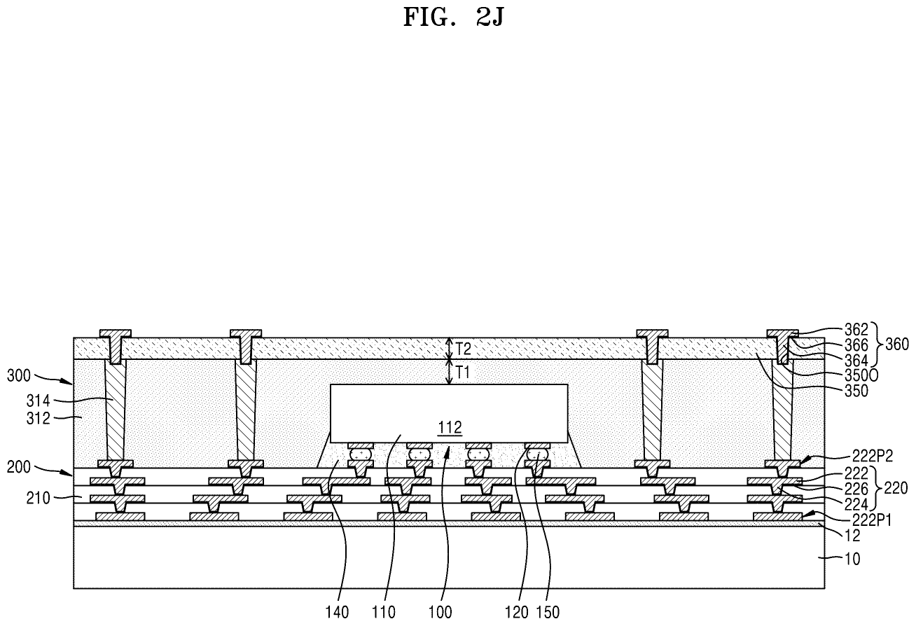

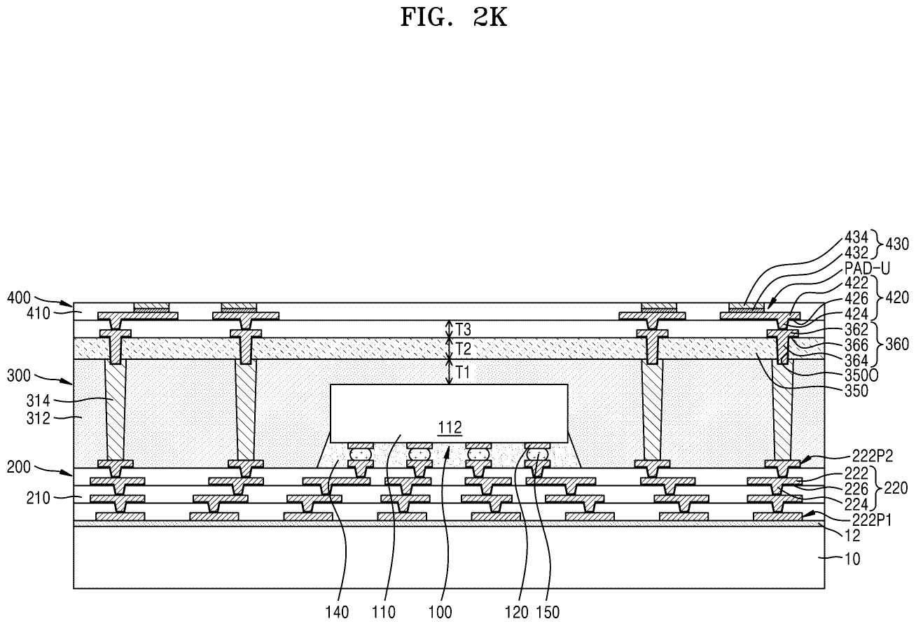

FIGS. 2A to 2K are cross-sectional views showing a method of manufacturing a semiconductor package, according to embodiments. In FIGS. 2A to 2K, the description already given with reference to FIG. 1 may be omitted.

Referring to FIG. 2A, a first support substrate 10 having a first release film 12 is attached thereon is prepared. The first support substrate 10 may be made of any material that is stable for subsequent processes, etc. In some embodiments, when the first support substrate 10 is to be separated and removed by laser ablation, the first support substrate 10 may be a light-transmitting substrate. In some other embodiments, when the first support substrate 10 is to be separated and removed by heating, the first support substrate 10 may be a heat-resistant substrate. For example, the first support substrate 10 may be a semiconductor substrate, a ceramic substrate, or a glass substrate. Alternatively, for example, the first support substrate 10 may be made of a heat-resistant organic polymer material, such as polyimide (PI), poly(etheretherketone) (PEEK), poly(ethersulfone) (PES), poly(phenylene sulfide) (PPS), but is not limited thereto. For example, the first release film 12 may include a laser-responsive layer or a heat-responsive layer that can separate the first support substrate 10 by being vaporized in response to subsequent laser irradiation or heating. In some embodiments, the first release film 12 may be made of a single layer or may have a multi-layer structure including release layers attached to both sides of a backbone layer, respectively. The backbone layer may be made of, for example, a thermoplastic polymer. For example, the release layer may be made of a copolymer of acrylic and silicone.

Referring to FIG. 2B, a first wiring structure 200 including a first redistribution insulating layer 210 and a plurality of first redistribution patterns 220 is formed on a first support substrate 10 to which a first release film 12 is attached. The plurality of first redistribution patterns 220 include a plurality of first redistribution line patterns 222, a plurality of first redistribution vias 224, and a plurality of first redistribution seed layers 226.

For example, the first redistribution insulating layer 210 may be formed by forming a first preliminary redistribution insulating layer and then removing portions of the first preliminary redistribution insulating layer through an exposure process and a development process. The first redistribution pattern 220 may be formed by forming a first preliminary redistribution seed layer and forming a first preliminary conductive layer on the first preliminary redistribution seed layer, and then removing a portion of the first preliminary redistribution seed layer and a portion of the first preliminary conductive layer. The remainder of the first preliminary redistribution seed layer may be the first redistribution seed layer 226, and the remaining portion of the first preliminary conductive layer may become a first redistribution line pattern 222 and a first redistribution via 224. Because the remaining portion of the first preliminary conductive layer after removing a portion of the first preliminary conductive layer becomes the first redistribution line pattern 222 and the first redistribution via 224, at least some of the plurality of first redistribution line patterns 222 may be formed to be integrated with at least some of the plurality of first redistribution vias 224. The first wiring structure 200 may be formed by repeatedly forming the first redistribution insulating layer 210 and the first redistribution patterns 220. The first redistribution pattern 220 may be formed on the first support substrate 10 to which the first release film 12 is attached, or may be formed on the first redistribution insulating layer 210.

The first wiring structure 200 may be formed by repeatedly forming the first redistribution insulating layer 210 and the first redistribution patterns 220. The first redistribution line patterns 222 formed to be disposed on the lower surface of the first wiring structure 200 may include a plurality of lower surface connection pads 222P1, and the first redistribution line patterns 222 formed on the upper surface of the first wiring structure 200 may include a plurality of extended connection pads 222P2. In some embodiments, the plurality of expansion connection pads 222P2 may be formed to protrude from the upper surface of the uppermost first redistribution insulating layer 210.

Referring to FIG. 2C, a mask pattern (not shown) having a plurality of mask holes (not shown) is formed on the first wiring structure 200, and then a plurality of connection structures 314 are formed to fill the plurality of mask holes. Some of the plurality of expansion connection pads 222P2 may be exposed on the bottom of the plurality of mask holes, and the remainder of the plurality of expansion connection pads 222P2 may be covered by the mask pattern and may not be exposed. After forming the plurality of connection structures 314, the mask pattern may be removed.

Referring to FIG. 2D, at least one semiconductor chip 100 including a plurality of chip pads 120 is attached on the first wiring structure 200. The semiconductor chip 100 may be attached on the first wiring structure 200 such that a plurality of chip connection members 150 are between the plurality of chip pads 120 and another portion of the plurality of expansion connection pads 222P2 of the first wiring structure 200. The semiconductor chip 100 may be attached to the first wiring structure 200 so as to be horizontally spaced apart from the plurality of connection structures 314. In some embodiments, after forming the plurality of chip connection members 150 on the plurality of chip pads 120 of at least one semiconductor chip 100, the at least one semiconductor chip 100 on which the plurality of chip connection members 150 are formed may be attached to the first wiring structure 200. At least one semiconductor chip 100 may be attached to the first wiring structure 200 such that the upper surface of the at least one semiconductor chip 100 is positioned at a vertical level lower than the uppermost surface of the plurality of connection structures 314.

In some embodiments, after attaching at least one semiconductor chip 100 on the first wiring structure 200, a bake process to remove moisture from the first wiring structure 200, the plurality of connection structures 314, and at least one semiconductor chip 100, and/or a plasma treatment for particle removal and surface treatment may be performed.

Referring to FIG. 2E, after forming an underfill layer 140 that fills the space between at least one semiconductor chip 100 and the first wiring structure 200, a preliminary encapsulant 312P is formed on the first wiring structure 200 to cover the plurality of connection structures 314 and the at least one semiconductor chip 100. The underfill layer 140 may be formed to surround the plurality of chip connection members 150. For example, the underfill layer 140 may be formed to fill the space between the at least one semiconductor chip 100 and the first wiring structure 200 and cover a portion of lower part of the side surface of the at least one semiconductor chip 100. The plurality of connection structures 314 and the preliminary encapsulant 312P may be collectively referred to as the preliminary expanded layer 300P. The preliminary encapsulant 312P may be formed to have an upper surface positioned at a higher vertical level than the upper surface of the plurality of connection structures 314 so as to cover the entire upper surface of each of the plurality of connection structures 314. The preliminary encapsulant 312P may be made of a molding member containing epoxy mold compound.

In some embodiments, the underfill layer 140 may not be formed. For example, the preliminary encapsulant 312P may be formed using a molded underfill (MUF) method that surrounds the plurality of chip connection members 150 and fills the space between at least one semiconductor chip 100 and the first wiring structure 200.

Referring to FIGS. 2F and 2G together, by removing a portion of the upper part of the preliminary expanded layer 300P, the expanded layer 300 including the encapsulation material 312 and a plurality of connection structures 314 may be formed. For example, a portion of the upper part of the preliminary encapsulant 312P is removed to form the encapsulant 312. The expanded layer 300 may be formed by removing a portion of the upper side of the preliminary expanded layer 300P such that the upper surface of the encapsulant 312 and the upper surface of the plurality of connection structures 314 are located at the same vertical level and are coplanar with each other. The encapsulant 312 may be formed to have a first thickness T1 on the upper surface of the semiconductor chip 100.

In some embodiments, the expanded layer 300 may be formed by removing a portion of upper part of the preliminary encapsulant 312P using a grinder 50 or performing a CMP process. In some other embodiments, the expanded layer 300 may be formed by removing a portion of the upper part of the preliminary encapsulant 312P and a portion of the upper part of the plurality of connection structures 314.

Referring to FIG. 2H, a ceramic shield layer 350 is formed on the expanded layer 300. The ceramic shield layer 350 may be formed to have a substantially constant thickness. For example, the ceramic shield layer 350 may be formed such that the lower surface of the ceramic shield layer 350 is a generally flat surface extending along the same vertical level. For example, the ceramic shield layer 350 may be formed so that the upper surface of the ceramic shield layer 350 is a generally flat surface extending along the same vertical level. The lower surface of the ceramic shield layer 350 may be positioned at the same vertical level as the upper surface of the encapsulant 312 and the uppermost surface of the plurality of connection structures 314. For example, the lower surface of the ceramic shield layer 350 may contact the upper surface of the encapsulant 312 and the uppermost surface of the plurality of connection structures 314.

The ceramic shield layer 350 may be formed to have a second thickness T2. In some embodiments, the second thickness T2 may have a value less than the first thickness T1. For example, the second thickness T2 may be about 5 μm to about 10 μm. In some embodiments, the ceramic shield layer 350 may be manufactured in the form of a film containing a mixture of ceramic material and resin and then attached to the expanded layer 300. In some other embodiments, the ceramic shield layer 350 may be formed in a slurry form and then coated on the expanded layer 300 by applying a coating method.

Referring to FIG. 2I, a plurality of through holes 350O that penetrate the ceramic shield layer 350 are formed. A plurality of connection structures 314 may be exposed on the bottom of the plurality of through holes 350O. The plurality of through holes 350O may be formed to penetrate the ceramic shield layer 350 through mechanical drilling or laser drilling. In some embodiments, the plurality of through holes 350O may be formed to extend through the ceramic shield layer 350 into the plurality of connection structures 314.

Referring to FIG. 2J, a plurality of via structures 360 connected to a plurality of connection structures 314 are formed through a plurality of through holes 350O. The plurality of via structures 360 may fill the plurality of through holes 350O. Each of the plurality of via structures 360 may include a pad pattern portion 362, a through via portion 364, and a via seed layer 366. The plurality of via structures 360 may be formed by forming a preliminary via seed layer, forming a conductive material layer on the preliminary via seed layer, and then removing a portion of the preliminary via seed layer and a portion of the conductive material layer, wherein the preliminary via seed layer conformally covers the upper surface of the ceramic shield layer 350 and the bottom and inner surfaces of the plurality of through holes 350O. The remainder of the preliminary via seed layer may be the via seed layer 366, and the remainder of the conductive material layer may be the pad pattern portion 362 and the through via portion 364. Because the remaining portion of the conductive material layer after removing a portion of the conductive material layer becomes the pad pattern portion 362 and the through via portion 364, the pad pattern portion 362 and the through via portion 364, which correspond to and are connected to each other, may be formed together to form one body.

The pad pattern portion 362 may be disposed on the upper surface of the ceramic shield layer 350. The through via portion 364 may penetrate the ceramic shield layer 350 from the pad pattern portion 362 and be in contact with the connection structure 314. The through via portion 364 may fill the through hole 350O. The via seed layer 366 may cover the lower portion of the pad pattern portion 362 and the through via portion 364 that are integrated with each other.

In some embodiments, the lower surface of the through via portion 364 may be at a lower vertical level than the lower surface of the ceramic shield layer 350. For example, the through via portion 364 may extend from the lower surface of the pad pattern portion 362 into the connection structure 314 through the through hole 350O. The lower surface of the through via portion 364 may be at a vertical level lower than the uppermost surface of the connection structure 314.

Referring to FIG. 2K, a second wiring structure 400 including a second redistribution insulating layer 410 and a plurality of second redistribution patterns 420 is formed on the ceramic shield layer 350 and the plurality of via structures 360, wherein the plurality of second redistribution patterns 420 includes a plurality of second redistribution line patterns 422, a plurality of second redistribution vias 424, and a plurality of second redistribution seed layers 426. The second redistribution insulating layer 410 may be formed to have a third thickness T3. In some embodiments, the third thickness T3 may have a value smaller than the second thickness T2. For example, the third thickness T3 may be about 3 μm to about 7 μm.

For example, the second redistribution insulating layer 410 may be formed by forming a second preliminary redistribution insulating layer and then removing portions of the second preliminary redistribution insulating layer through an exposure process and a development process. The second redistribution pattern 420 is formed by forming a second preliminary redistribution seed layer, forming a second preliminary conductive layer on the second preliminary redistribution seed layer, and then removing a portion of the second preliminary redistribution seed layer and a portion of the second preliminary conductive layer. The remainder of the second preliminary redistribution seed layer may be the second redistribution seed layer 426, and the remaining portion of the second preliminary conductive layer may become the second redistribution line pattern 422 and the second redistribution via 424. Because the remaining portion of the second preliminary conductive layer after removing a portion of the second preliminary conductive layer becomes the second redistribution line pattern 422 and the second redistribution via 424, at least some of the plurality of second redistribution line patterns 422 may be formed to be integrated with at least some of the plurality of second redistribution vias 424. The second wiring structure 400 may be formed by repeatedly forming the second redistribution insulating layer 410 and the second redistribution patterns 420.

The plurality of second redistribution patterns 420 may be electrically connected to the plurality of via structures 360. For example, among the plurality of second redistribution vias 424, each of the lowermost second redistribution vias 424 may be connected in contact with the pad pattern portion 362 of each of the plurality of via structures 360.

The second wiring structure 400 may be formed by repeatedly forming the second redistribution insulating layer 410 and the second redistribution patterns 420. The second wiring structure 400 may be formed to include a plurality of upper surface connection pads PAD-U disposed on the upper surface of the second wiring structure 400. In some embodiments, each of the plurality of upper surface connection pads PAD-U may be formed to include a portion of the second redistribution line pattern 422 and an upper surface connection pad layer 430 covering an upper surface of the portion of the second redistribution line pattern 422. The upper surface connection pad layer 430 may be formed to include a first upper surface metal layer 432 and a second upper surface metal layer 434 sequentially stacked on the second redistribution line pattern 422.

Thereafter, the first support substrate 10 to which the first release film 12 is attached may be removed, and a plurality of external connection terminals 500 may be attached to the plurality of lower surface connection pads 222P1 as shown in FIG. 1 to form the semiconductor package 1.

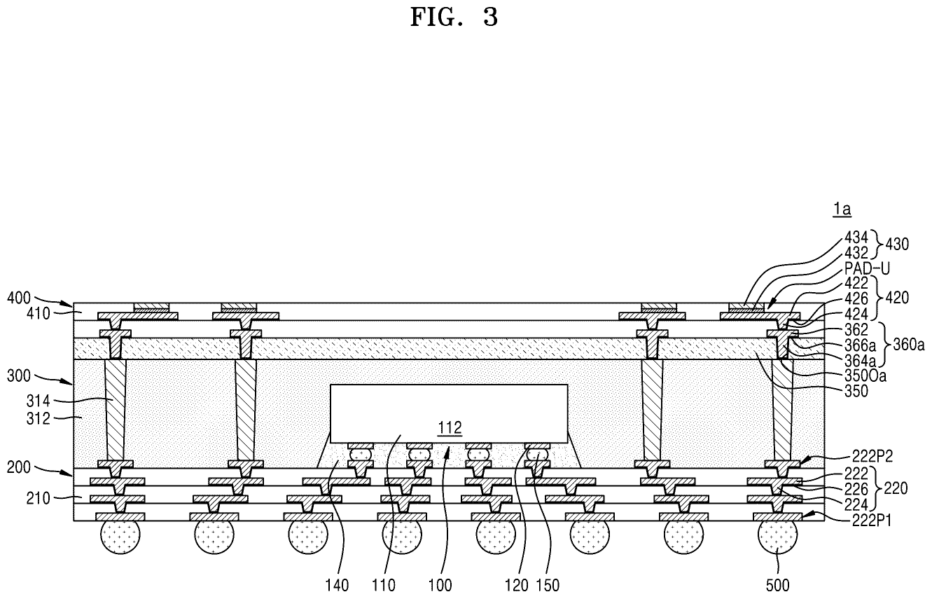

FIGS. 3 to 6 are cross-sectional views of semiconductor packages according to embodiments.

Referring to FIG. 3, a semiconductor package la includes a ceramic shield layer 350 with a plurality of through holes 350Oa and a plurality of via structures 360a each including a pad pattern portion 362, a through via portion 364a, and a via seed layer 366a, instead of the ceramic shield layer 350 with the plurality of through holes 350O and a plurality of via structures 360 each including the pad pattern portion 362, the through via portion 364, and the via seed layer 366, included in the semiconductor package 1 shown in FIG. 1.

The plurality of through holes 350Oa may be formed to penetrate the ceramic shield layer 350. In some embodiments, the plurality of through holes 350Oa may be formed to penetrate the ceramic shield layer 350 but not extend into the plurality of connection structures 314. The plurality of via structures 360a may fill a plurality of through holes 350Oa. The lower surface of the plurality of via structures 360a may be at the same vertical level as the lower surface of the ceramic shield layer 350. For example, the through via portion 364a may contact the upper surface of the connection structure 314 from the lower surface of the pad pattern portion 362 through the through hole 350Oa. The lower surface of the ceramic shield layer 350 and the lower surface of the plurality of via structures 360a may be at the same vertical level to form a coplanar surface. The upper surface of the encapsulant 312 and the upper surface of the plurality of connection structures 314 may be at the same vertical level and form a coplanar surface.

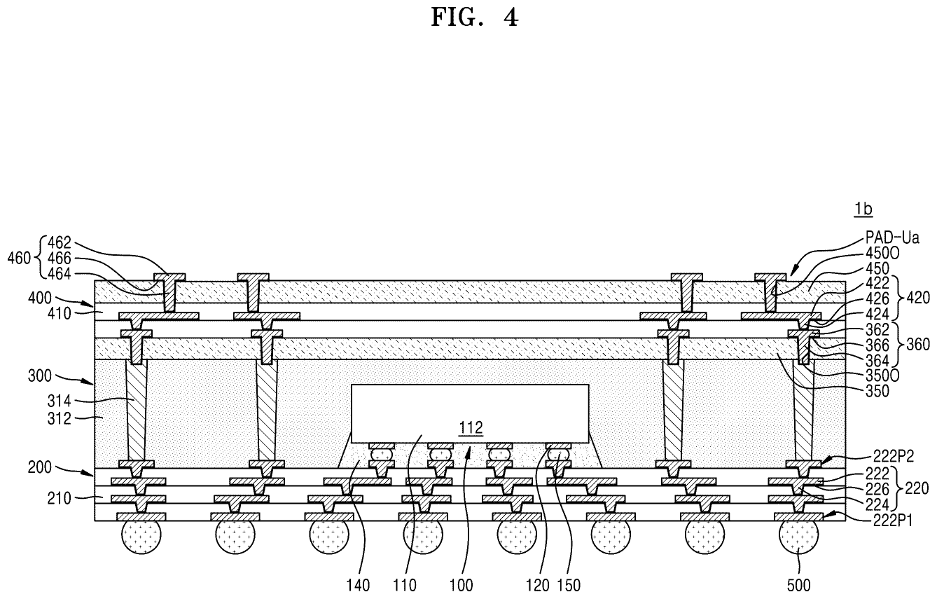

Referring to FIG. 4, unlike the semiconductor package 1 shown in FIG. 1, a semiconductor package 1b further includes an upper ceramic shield layer 450 having a plurality of upper through holes 450O and a plurality of upper via structures 460 each including an upper pad pattern portion 462, an upper through via portion 464, and an upper via seed layer 466. The upper ceramic shield layer 450 having the plurality of upper through holes 450O and the plurality of upper via structures 460 each including the upper pad pattern portion 462, the upper through via portion 464, and the upper via seed layer 466 are generally similar to the ceramic shield layer 350 having the plurality of through holes 350O and the plurality of via structures 360 each including the pad pattern portion 362, the through via portion 364, and the via seed layer 366 shown in FIG. 1, respectively. Accordingly, the descriptions already given may be omitted.

The upper ceramic shield layer 450 may be formed to cover the second wiring structure 400. The plurality of upper through holes 450O may penetrate the upper ceramic shield layer 450, and portions of the plurality of second redistribution patterns 420 may be exposed on the bottom surface of the plurality of upper through holes 450O. In some embodiments, on the bottom surface of the plurality of upper through holes 450O, portions of the uppermost second redistribution line pattern 422 among the plurality of second redistribution line patterns 422 may be exposed. The plurality of upper via structures 460 may be electrically connected to the plurality of second redistribution patterns 420. In some embodiments, the lower surfaces of the plurality of upper via structures 460 be in contact with and connected to the upper surfaces of portions of the uppermost second redistribution line pattern 422 among the plurality of second redistribution line patterns 422. In some embodiments, the plurality of upper via structures 460 may extend into the uppermost second redistribution insulating layer 410 and be connected to the plurality of second redistribution patterns 420.

In some embodiments, the semiconductor package 1b may not include a plurality of upper surface connection pad layers 430 included in the semiconductor package 1 shown in FIG. 1. For example, a plurality of upper pad pattern portions 462 may be a plurality of upper surface connection pads PAD-Ua. In some other embodiments, the semiconductor package 1b may further include the plurality of upper surface connection pad layers 430 shown in FIG. 1 on the plurality of upper pad pattern portions 462. For example, the plurality of upper surface connection pads PAD-Ua may include a plurality of upper pad pattern portions 462 and the plurality of upper surface connection pad layers 430 covering the plurality of upper pad pattern portions 462.

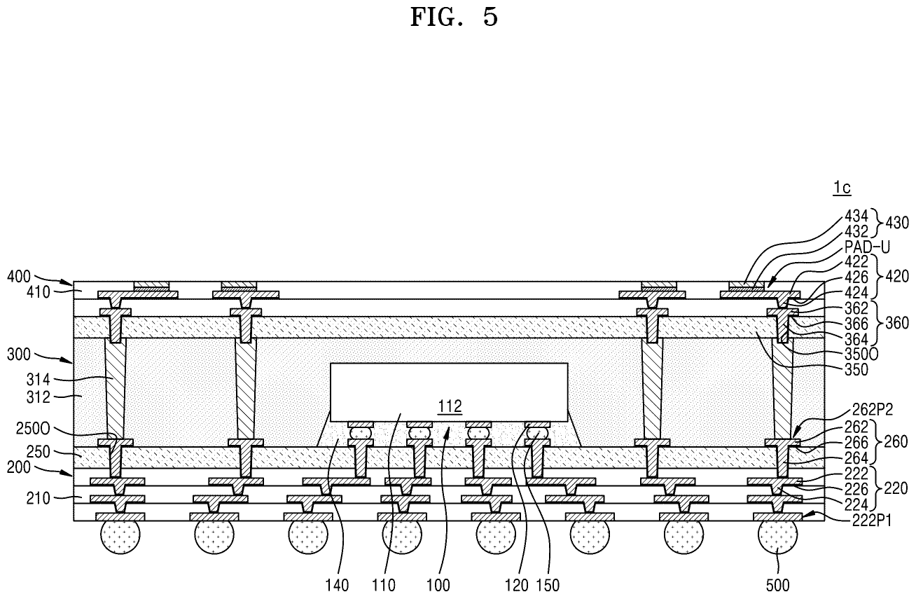

Referring to FIG. 5, unlike the semiconductor package 1 shown in FIG. 1, a semiconductor package 1c further includes a lower ceramic shield layer 250 having a plurality of lower through holes 250O and a plurality of lower via structures 260 each including a lower pad pattern portion 262, a lower through via portion 264, and a lower via seed layer 266. The lower ceramic shield layer 250 having the plurality of lower through holes 250O and the plurality of lower via structures 260 each including a lower pad pattern portion 262, a lower through via portion 264, and a lower via seed layer 266 are generally similar to the ceramic shield layer 350 having the plurality of through holes 350O and the plurality of via structures 360 each including the pad pattern portion 362, the through via portion 364, and the via seed layer 366 shown in FIG. 1, respectively. Accordingly, the descriptions already given may be omitted.

The lower ceramic shield layer 250 may be formed to cover the first wiring structure 200. The plurality of lower through holes 250O may penetrate the lower ceramic shield layer 250, and portions of the plurality of first redistribution patterns 220 may be exposed on the bottom surface. In some embodiments, on the bottom of the plurality of lower through holes 250O, portions of the uppermost first redistribution line pattern 222 among the plurality of first redistribution line patterns 222 may be exposed. The plurality of lower via structures 260 may be electrically connected to the plurality of first redistribution patterns 220. In some embodiments, the lower surfaces of the plurality of lower via structures 260 may be connected in contact with the upper surfaces of portions of the uppermost first redistribution line patterns 222 among the plurality of first redistribution line patterns 222. In some embodiments, the plurality of lower via structures 260 may extend into the uppermost first redistribution insulating layer 210 and be connected to the plurality of first redistribution patterns 220.

The plurality of lower pad pattern portions 262 may be a plurality of expansion connection pads 262P2. A plurality of connection structures 314 may be attached to some of the plurality of expansion connection pads 262P2, and a plurality of chip connection members 150 may be attached to some other of the plurality of expansion connection pads 262P2.

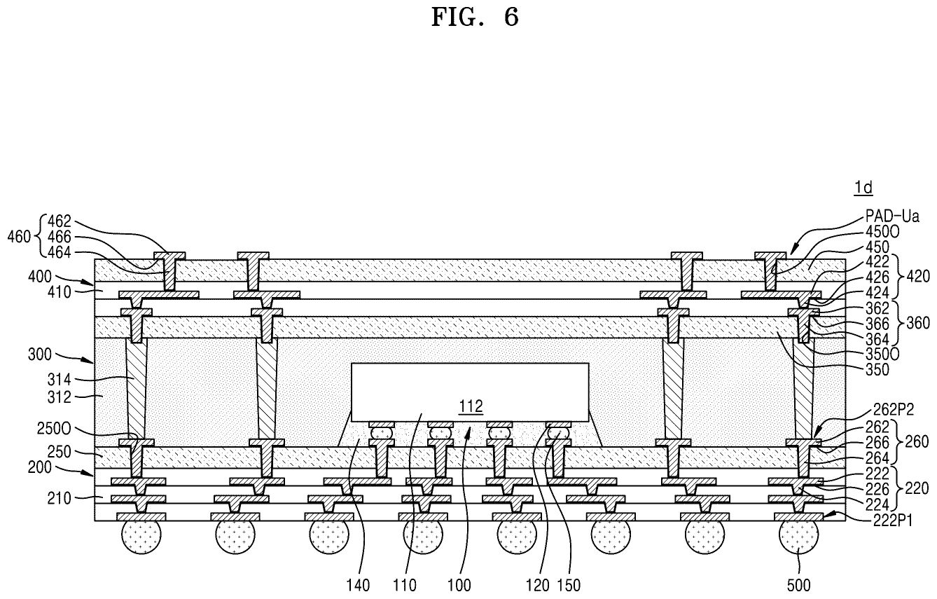

Referring to FIG. 6, unlike the semiconductor package 1 shown in FIG. 1, a semiconductor package 1d further includes the upper ceramic shield layer 450 having the plurality of upper through holes 450O and the plurality of upper via structures 460 each including the upper pad pattern portion 462, the upper through via portion 464, and the upper via seed layer 466 shown in FIG. 4 and the lower ceramic shield layer 250 having the plurality of lower through holes 250O and the plurality of lower via structures 260 each including the lower pad pattern portion 262, the lower through via portion 264, and the lower via seed layer 266 shown in FIG. 5.

Referring to FIGS. 4 to 6 together with FIG. 3, the semiconductor packages 1b, 1c, and 1d shown in FIGS. 4 to 6 may include the ceramic shield layer 350 having the plurality of through holes 350Oa and the plurality of via structures 360a each including the pad pattern portion 362, the through via portion 364a, and a via seed layer 366a shown in FIG. 3 instead of the ceramic shield layer 350 having a plurality of through holes 350O and the plurality of via structures 360 each including the pad pattern portion 362, the through via portion 364, and the via seed layer 366.

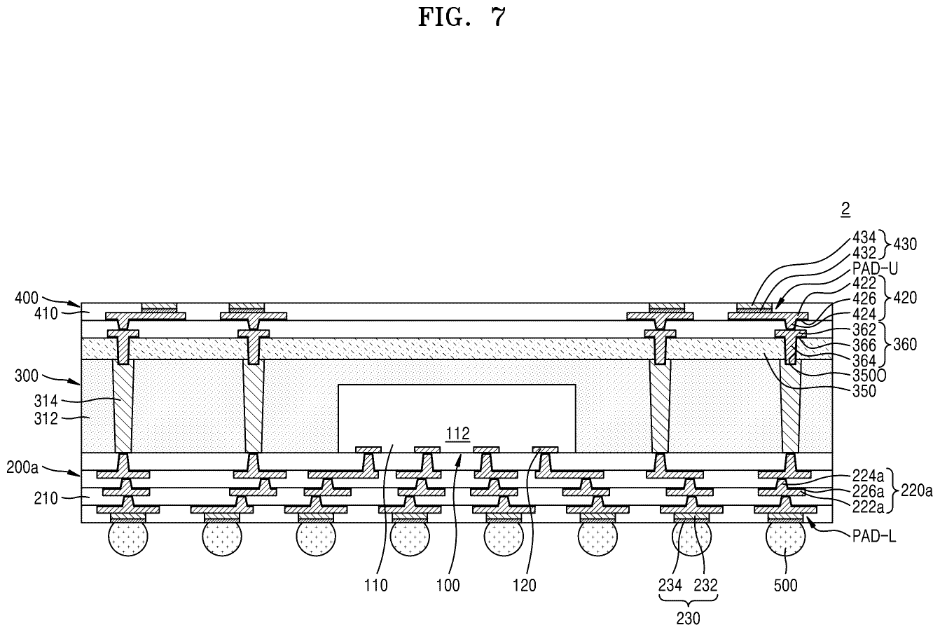

FIG. 7 is a cross-sectional view of a semiconductor package according to an embodiment.

Referring to FIG. 7, instead of the first wiring structure 200 included in the semiconductor package 1 shown in FIG. 1, a semiconductor package 2 may include a first wiring structure 200a.

The first wiring structure 200a may include a first redistribution insulating layer 210 and a plurality of first redistribution patterns 220a. The plurality of first redistribution patterns 220a may include a plurality of first redistribution line patterns 222a, a plurality of first redistribution vias 224a, and a plurality of first redistribution seed layers 226a. The first redistribution insulating layer 210 included in the first wiring structure 200a and the plurality of first redistribution patterns 220a are generally similar to the first redistribution insulating layer 210 included in the first wiring structure 200 and the plurality of first redistribution patterns 220 shown in FIG. 1. Accordingly, descriptions already given may be omitted.

The plurality of first redistribution vias 224a may penetrate through at least one first redistribution insulating layer 210 and may each be in contact with and connected to some of the plurality of first redistribution line patterns. In some embodiments, the plurality of first redistribution vias 224a may have a tapered shape extending with a horizontal width that increases from the top to the bottom. For example, the horizontal width of the plurality of first redistribution vias 224a may increase as the first redistribution via 224a moves away from the at least one semiconductor chip 100.

In some embodiments, at least some of the plurality of first redistribution line patterns 222a may be formed together with some of the plurality of first redistribution vias 224a to form an integrated unit. For example, the first redistribution line pattern 222a and the first redistribution via 224a in contact with the upper surface of the first redistribution line pattern 222a, that is, the first redistribution via 224a extending from the upper surface of the first redistribution line pattern 224a, may be formed together to form an integrated unit. For example, the horizontal width of each of the plurality of first redistribution vias 224a may become narrower as each of the plurality of first redistribution vias 224a moves away from the integrated first redistribution line pattern 222a. The first redistribution seed layer 226a may cover the lower portion of the first redistribution line pattern 222a and the first redistribution via 224a that are integrated with each other. For example, the first redistribution seed layer 226a may cover the upper surface of the first redistribution line pattern 222a and the side and upper surfaces of the first redistribution via 224a, among the surfaces of the first redistribution line pattern 222a and the first redistribution via 224a, which are integrated with each other. The first redistribution seed layer 226a may not cover the side and lower surfaces of the first redistribution line pattern 222a.

A plurality of chip pads 120 may be connected in contact with some of the first redistribution vias 224a at the top, and a plurality of connection structures 314 may be connected to some other of the first redistribution vias 224a at the top. In some embodiments, the lower surface of at least one semiconductor chip 100, the lower surface of the encapsulant 312, and the lower surface of the plurality of connection structures 314 may be positioned at the same vertical level to form a coplanar surface. In some embodiments, the semiconductor package 2 may be formed in a chip-first manner by first forming an expanded layer 300 and at least one semiconductor chip 100, and then forming a first wiring structure 200a. In some embodiments, the upper surface of the uppermost first redistribution insulating layer 210 and the upper surface of the uppermost first redistribution via 224a may be at the same vertical level and form a coplanar surface.

The first wiring structure 200a may include a plurality of lower surface connection pads PAD-L disposed on the lower surface of the first wiring structure 200a. In some embodiments, each of the plurality of bottom connection pads PAD-L may include a portion of the first redistribution line pattern 222a and a lower surface connection pad layer 230 covering a lower surface of the portion of the first redistribution line pattern 222a. The bottom connection pad layer 230 may include a first lower surface metal layer 232 and a second lower surface metal layer 232 sequentially stacked on the lower surface of a portion of the first redistribution line pattern 222a. In some embodiments, the first lower metal layer 232 may include nickel (Ni), and the second lower metal layer 234 may include gold (Au), but are not limited thereto. A plurality of external connection terminals 500 may be attached to the plurality of lower surface connection pads PAD-L. The plurality of external connection terminals 500 may connect the semiconductor package 2 to the outside.

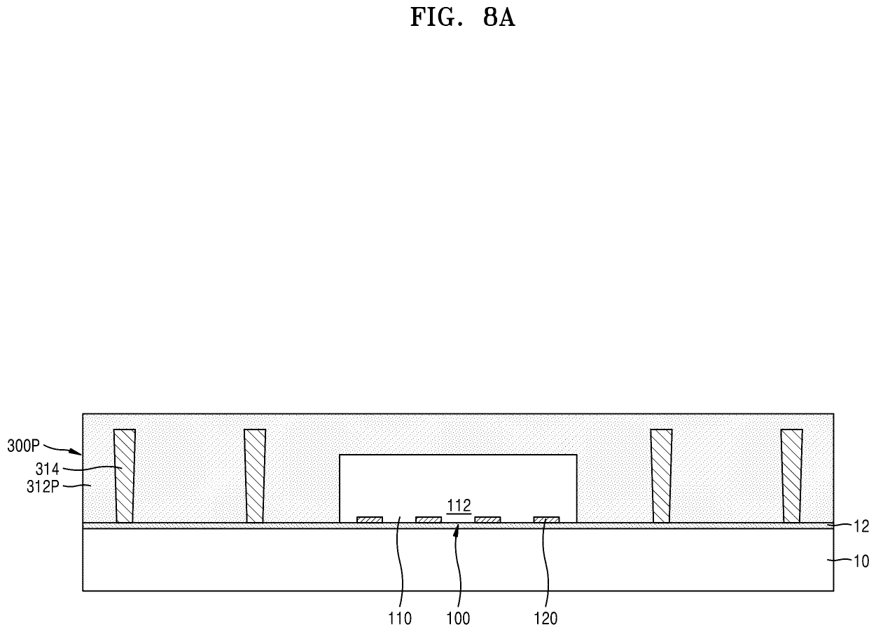

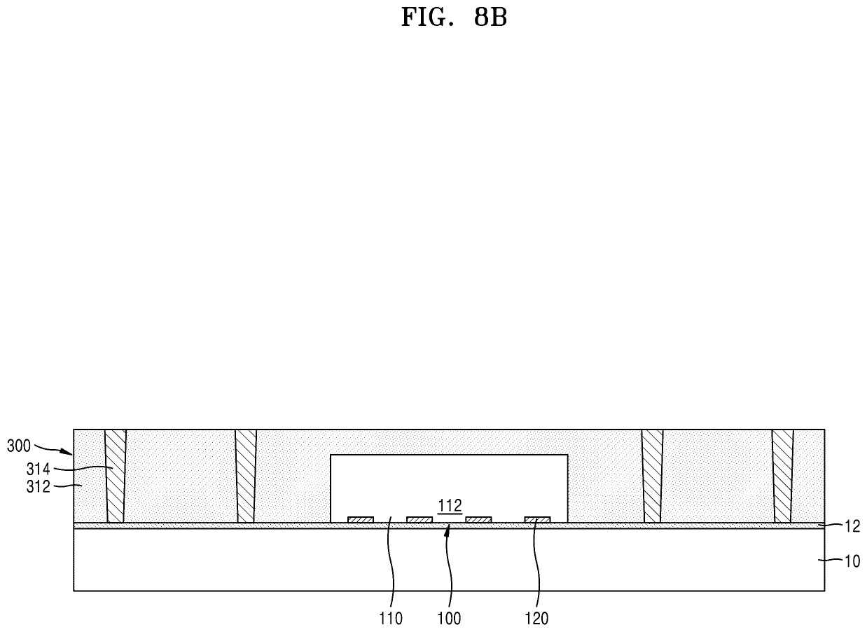

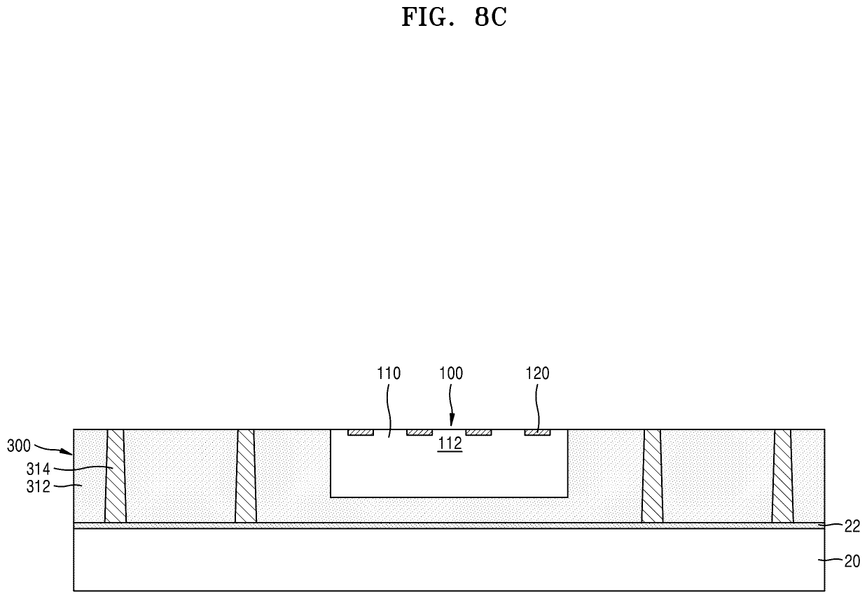

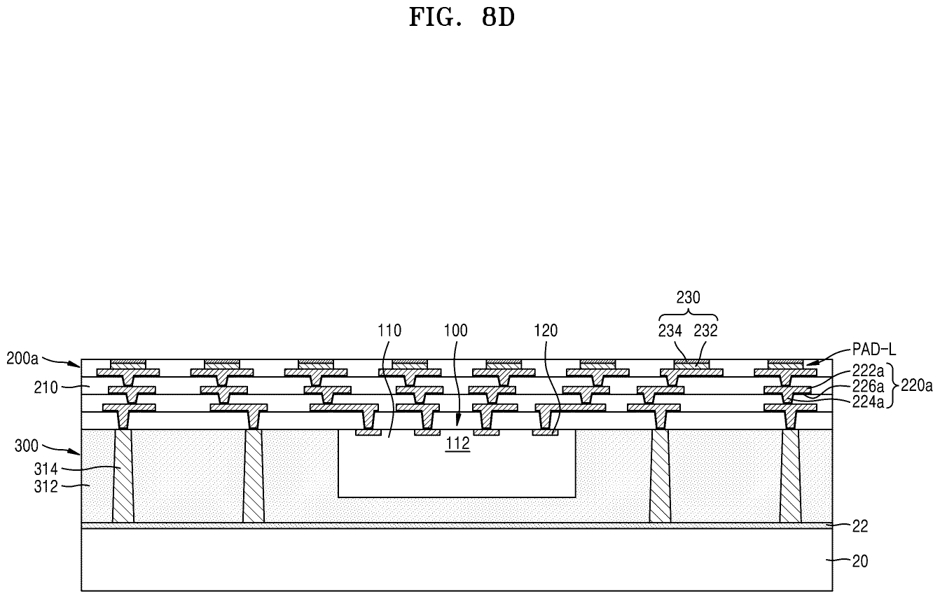

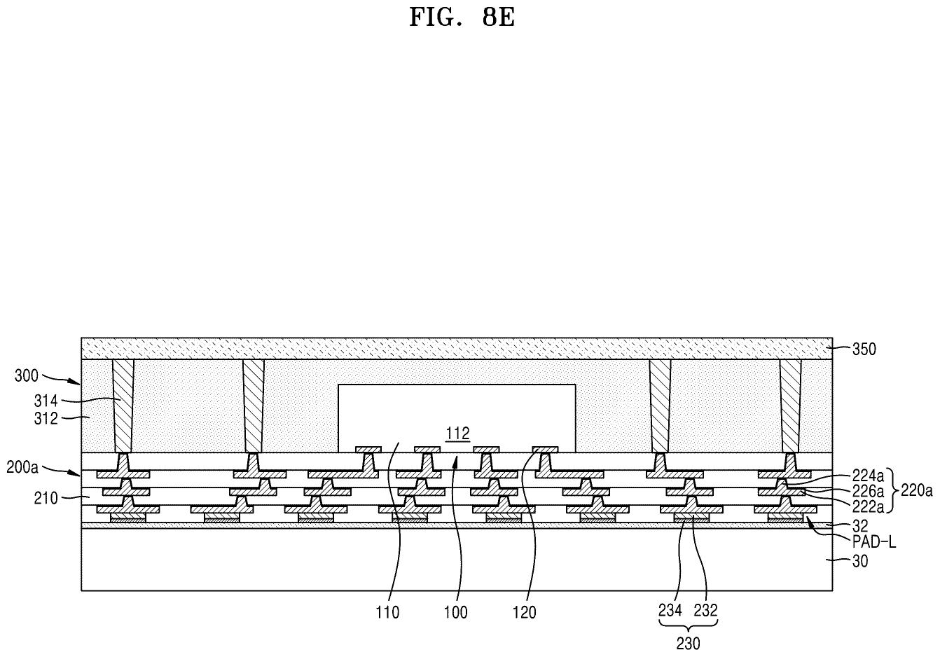

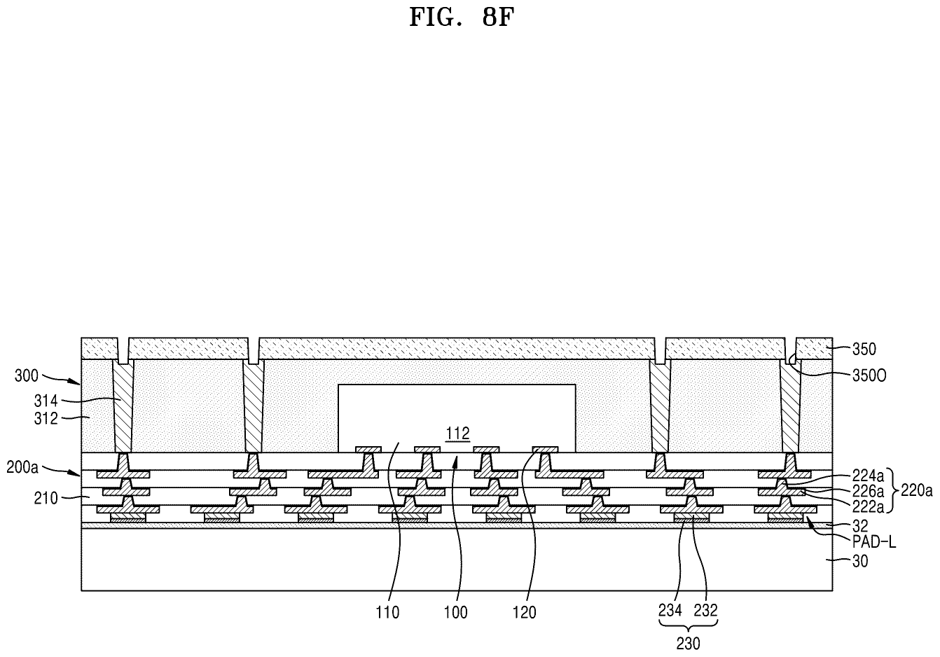

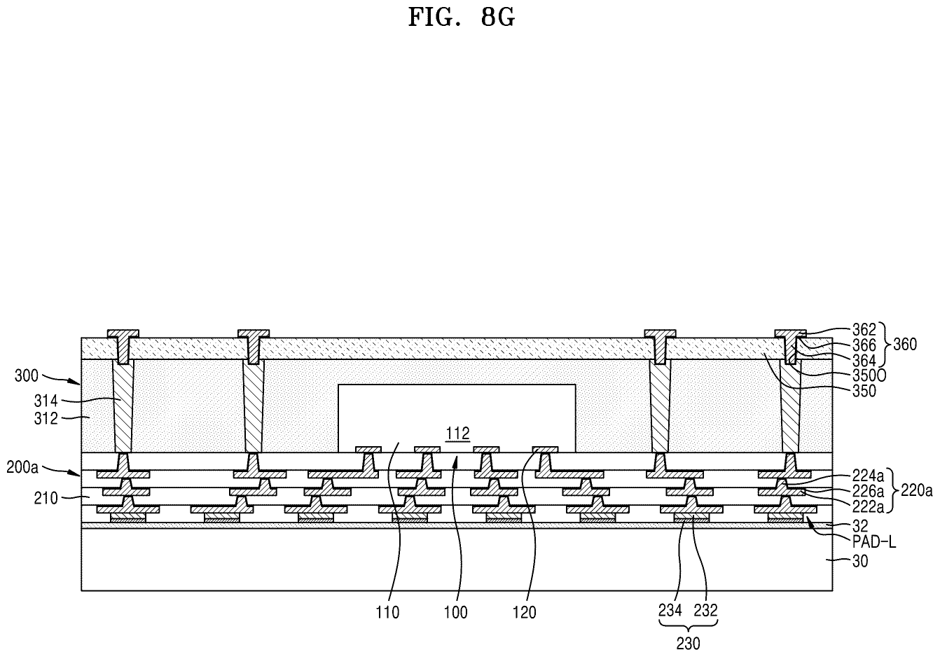

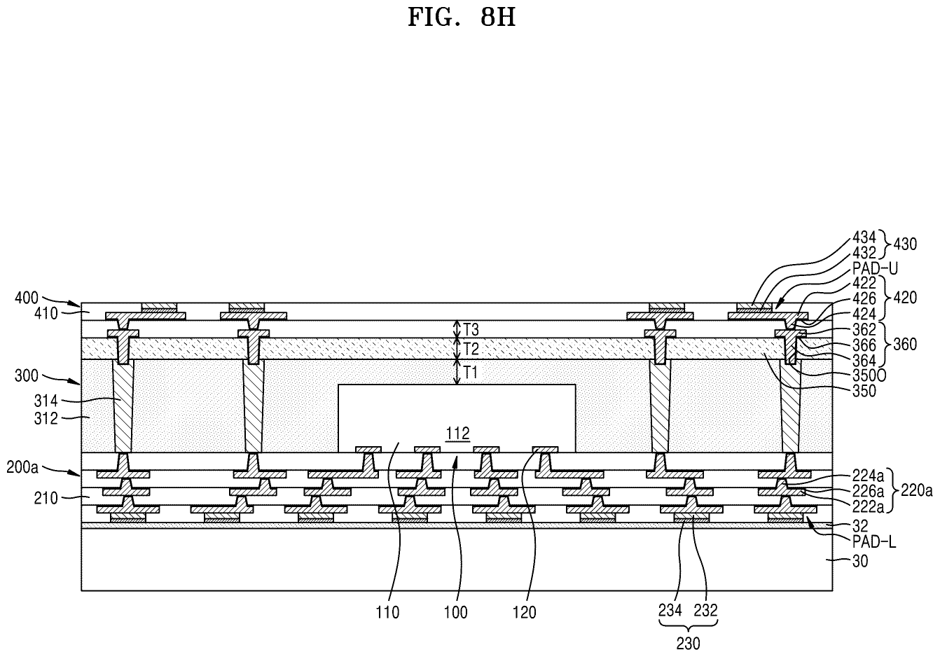

FIGS. 8A to 8H are cross-sectional views showing a method of manufacturing a semiconductor package, according to embodiments. In FIGS. 8A to 8H, the description already given with reference to FIGS. 2A to 2K and FIG. 7 may be omitted.

Referring to FIG. 8A, a mask pattern (not shown) having a plurality of mask holes (not shown) is formed on a first support substrate 10 to which a first release film 12 is attached, and then a plurality of connection structures 314 are formed to fill the plurality of mask holes. The first release film 12 may be exposed on the bottom of the plurality of mask holes. After forming the plurality of connection structures 314, the mask pattern can be removed.

Thereafter, at least one semiconductor chip 100 including a plurality of chip pads 120 is attached to the first support substrate 10 to which the first release film 12 is attached. The semiconductor chip 100 may be attached to a first support substrate 10 to which the first release film 12 is attached so that a plurality of chip pads 120 are in contact with the first release film 12. The semiconductor chip 100 may be attached to the first support substrate 10 to which the first release film 12 is attached so that the semiconductor chip 100 is spaced apart from the plurality of connection structures 314 in the horizontal direction. At least one semiconductor chip 100 may be attached to the first support substrate 10 to which the first release film 12 is attached so that the upper surface of the at least one semiconductor chip 100 is at a vertical level lower than the uppermost surface of the plurality of connection structures 314.

After forming a plurality of connection structures 314 and attaching at least one semiconductor chip 100 on the first support substrate 10 to which the first release film 12 is attached, a preliminary encapsulant 312P is formed to cover the plurality of connection structures 314 and at least one semiconductor chip 100. The preliminary encapsulant 312P may be formed to have an upper surface located at a vertical level higher than the upper surface of the plurality of connection structures 314 so as to cover all of the upper surfaces of each of the plurality of connection structures 314.

Referring to FIGS. 8A and 8B together, by removing the upper portion of the preliminary expanded layer 300P, the expanded layer 300 including the encapsulant 312 and a plurality of connection structures 314 may be formed. For example, the upper portion of the preliminary encapsulant 312P is removed to form the encapsulant 312. The expanded layer 300 may be formed by removing a portion of the upper side of the preliminary expanded layer 300P such that the upper surface of the encapsulant 312 and the upper surface of the plurality of connection structures 314 are located at the same vertical level and are coplanar with each other.

Referring to FIGS. 8B and 8C together, after removing the first support substrate 10 to which the first release film 12 is attached from at least one semiconductor chip 100 and the expanded layer 300, the resulting product is turned upside down and attached to a second support substrate 20 to which a second release film 22 is attached. Because the second release film 22 and the second support substrate 20 are the same as (or substantially the same as) the first release film 12 and the first support substrate 10, descriptions already given may be omitted.

Referring to FIG. 8D, a first wiring structure 200a including a first redistribution insulating layer 210 and a plurality of first redistribution patterns 220a including a plurality of first redistribution line patterns 222a, a plurality of first redistribution vias 224a, and a plurality of first redistribution seed layers 226a is formed on at least one semiconductor chip 100 and the expanded layer 300.

The first wiring structure 200a may be formed by repeatedly forming the first redistribution insulating layer 210 and the first redistribution patterns 220a. A lower surface connection pad layer 230 may be formed on the first redistribution patterns 222a located at the top among the plurality of first redistribution patterns 220a, for example, on the first redistribution line patterns 222a at the top among the plurality of first redistribution line patterns 222a. The lower surface connection pad layer 230 may include a first bottom metal layer 232 and a second bottom metal layer 234 sequentially stacked on a portion of the first redistribution line pattern 222a. The lower surface connection pad layer 230 covering a portion of the first redistribution line pattern 222a and the lower surface of the portion of the first redistribution line pattern 222a may be a lower surface connection pad PAD-L.

Referring to FIGS. 8D and 8E together, after forming the first wiring structure 200a, the at least one semiconductor chip 100 and the second support substrate 20 to which the second release film 22 is attached is removed from the second support substrate 20, and then the resulting product is turned upside down and attached to a third support substrate 30 to which a third release film 32 is attached. Because the third release film 32 and the third support substrate 30 are the same (or substantially the same) as the first release film 12 and the first support substrate 10, the description already given may be omitted. Afterwards, a ceramic shield layer 350 is formed on the expanded layer 300.

Referring to FIGS. 8F and 8G together, a plurality of through holes 350O penetrating the ceramic shield layer 350 are formed, and a plurality of via structures 360 connected to the plurality of connection structures 314 are formed through the plurality of through holes 350O.

Referring to FIG. 8H, a second wiring structure 400 including a second redistribution insulating layer 410 and a plurality of second redistribution patterns 420 including a plurality of second redistribution line patterns 422, a plurality of second redistribution vias 424, and a plurality of second redistribution seed layers 426 is formed on the ceramic shield layer 350 and the plurality of via structures 360.

Thereafter, the third support substrate 30 to which the third release film 32 is attached may be removed, and a plurality of external connection terminals 500 may be attached to the plurality of bottom connection pads PAD-L as shown in FIG. 7 to form a semiconductor package 2.

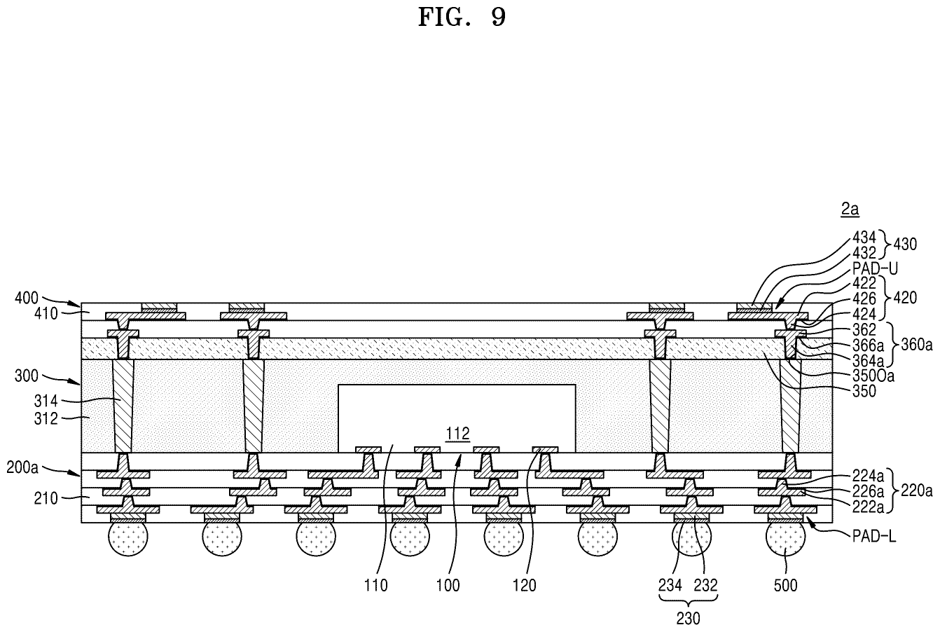

FIG. 9 is a cross-sectional view of a semiconductor package according to an embodiment.

Referring to FIG. 9, a semiconductor package 2a includes a ceramic shield layer 350 with a plurality of through holes 350Oa and a plurality of via structures 360a each including a pad pattern portion 362, a through via portion 364a, and a via seed layer 366a shown in FIG. 3, instead of the ceramic shield layer 350 with the plurality of through holes 350O and a plurality of via structures 360 each including the pad pattern portion 362, the through via portion 364, and the via seed layer 366, included in the semiconductor package 2 shown in FIG. 7.

Referring to FIGS. 7 to 9 together with FIGS. 4 to 6, the semiconductor packages 2 and 2a shown in FIGS. 7 to 9 may further include the upper ceramic shield layer 450 having the plurality of upper through holes 450O and the plurality of upper via structures 460 each including the upper pad pattern portion 462, the upper through via portion 464, and the upper via seed layer 466 shown in FIGS. 7 to 9, and may further include the lower ceramic shield layer 250 having the plurality of lower through holes 250O and the plurality of lower via structures 260 each including the lower pad pattern portion 262, the lower through via portion 264, and the lower via seed layer 266.

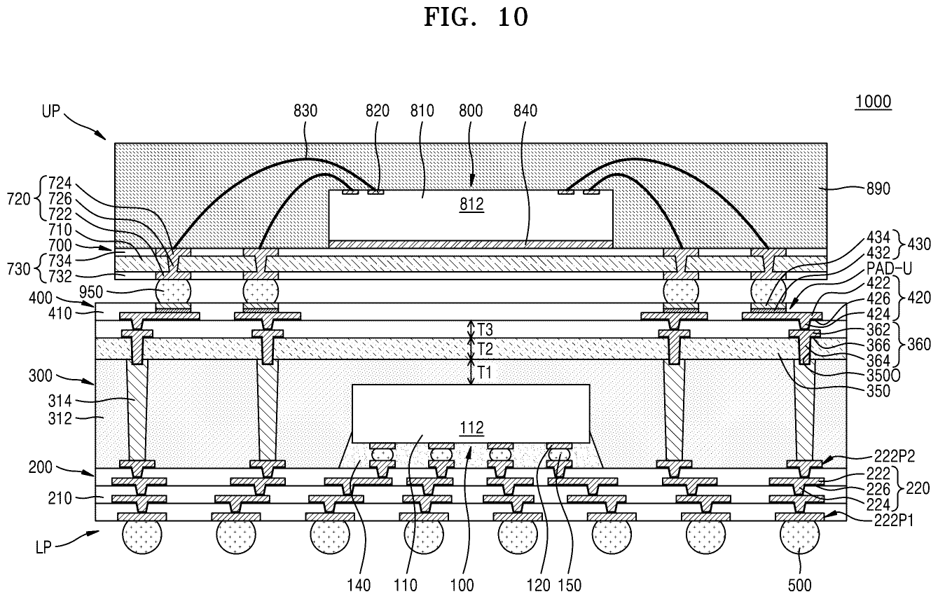

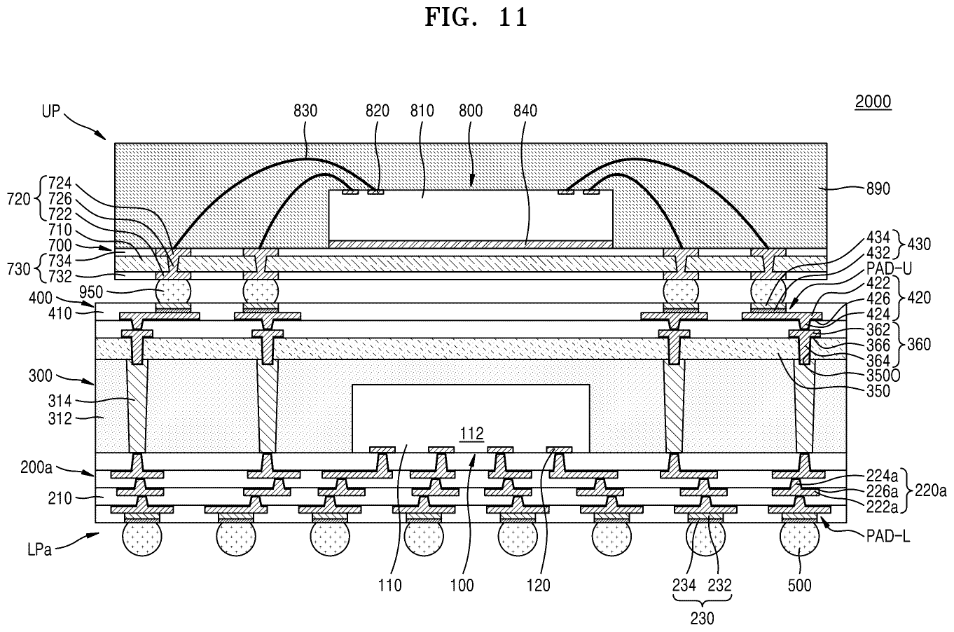

FIGS. 10 and 11 are cross-sectional views of a semiconductor package according to an embodiment.

Referring to FIG. 10, a semiconductor package 1000 may be a package-on-package (POP) that includes a lower package LP and an upper package UP attached to the lower package LP. The lower package LP before the upper package UP is attached may be called a semiconductor package, and the upper package UP before being attached to the lower package LP may also be called the semiconductor package. The lower package LP may be the semiconductor package 1 shown in FIG. 1. The lower package LP includes a first wiring structure 200, at least one semiconductor chip 100 on the first wiring structure 200, an expanded layer 300 surrounding the at least one semiconductor chip 100, a ceramic shield layer 350 on the expanded layer 300, and a second wiring structure 400 on the ceramic shield layer 350.

The upper package UP may be attached to the second wiring structure 400. For example, the upper package UP may be connected to the plurality of upper surface connection pads PAD-U. For example, a plurality of package connection terminals 950 may be between the upper package UP and the plurality of upper surface connection pads PAD-U. For example, the plurality of package connection terminals 950 may be attached to a plurality of upper surface connection pad layers 430. The plurality of package connection terminals 950 may electrically connect the lower package LP and the upper package UP to each other. In some embodiments, each of the plurality of package connection terminals 950 may be a bump, a solder ball, or the like.

The upper package UP includes a package substrate 700 and an auxiliary semiconductor chip 800 mounted on the package substrate 700. The auxiliary semiconductor chip 800 may include an auxiliary semiconductor substrate 810 having opposing active and inactive surfaces, an auxiliary semiconductor element 812 formed on the active side of the auxiliary semiconductor substrate 810, and a plurality of auxiliary chip pads 820 disposed on a third side of the auxiliary semiconductor chip 800. The third side of the auxiliary semiconductor chip 800 and the fourth side of the auxiliary semiconductor chip 800 are opposite to each other, and the fourth side of the auxiliary semiconductor chip 800 refers to the inactive side of the auxiliary semiconductor substrate 810. Because the active surface of the auxiliary semiconductor substrate 810 is very close to the third surface of the auxiliary semiconductor chip 800, separate illustration of the active surface of the auxiliary semiconductor substrate 810 and the third surface of the auxiliary semiconductor chip 800 is omitted.

The auxiliary semiconductor chip 800 may be a memory semiconductor chip. For example, the auxiliary semiconductor chip 800 may be a DRAM chip, an SRAM chip, a flash memory chip, an EPROM chip, a PRAM chip, an MRAM chip, or an RRAM chip. Because the auxiliary semiconductor substrate 810 and the auxiliary chip pad 820 are similar to the semiconductor substrate 110 and chip pad 120, detailed descriptions thereof are omitted. The semiconductor chip 100, the semiconductor substrate 110, the semiconductor device 112, and the chip pad 120 may be referred to as a first semiconductor chip, a first semiconductor substrate, a first semiconductor device, and a first chip pad, or a lower semiconductor chip, a lower semiconductor substrate, a lower semiconductor device, and a lower chip pad, respectively. The auxiliary semiconductor chip 800, auxiliary semiconductor substrate 810, auxiliary semiconductor element 812, and auxiliary chip pad 820 may be referred to as a second semiconductor chip, a second semiconductor substrate, a second semiconductor element, and a second chip pad, or an upper semiconductor chip, an upper semiconductor substrate, an upper semiconductor element, and an upper chip pad, respectively.

In some embodiments, the auxiliary semiconductor chip 800 may be electrically connected to the package substrate 700 through a plurality of bonding wires 830 connected to a plurality of auxiliary chip pads 820 and may be mounted on the package substrate 700 using a die attach film (DAF) 840. In some embodiments, the upper package UP may include a plurality of auxiliary semiconductor chips 800 spaced apart from each other in the horizontal direction, or may include a plurality of auxiliary semiconductor chips 800 stacked in the vertical direction. Alternatively, the upper package UP may include a plurality of auxiliary semiconductor chips 800 that are electrically connected through a through electrode and stacked in a vertical direction. Alternatively, the auxiliary semiconductor chip 800 may be mounted on the package substrate 700 using a flip chip method.

The package substrate 700 may be a printed circuit board. For example, the package substrate 700 may be a double-sided printed circuit board or a multi-layer printed circuit board. The package substrate 700 may include at least one base insulating layer 710 and a plurality of wiring patterns 720. The plurality of wiring patterns 720 may include a plurality of bottom conductive patterns 722, a plurality of upper surface conductive patterns 724, and a plurality of via patterns 726. The plurality of bottom conductive patterns 722 may be disposed on the lower surface of the base insulating layer 710, a plurality of upper surface conductive patterns 724 may be disposed on the upper surface of the base insulating layer 710, and the plurality of via patterns 726 may penetrate the base insulating layer 710 to connect the plurality of bottom conductive patterns 722 and the plurality of upper surface conductive patterns 724 to each other.

The base insulating layer 710 may be made of at least one material selected from phenol resin, epoxy resin, and polyimide. The base insulating layer 710 may include at least one material selected from, for example, frame retardant 4 (FR-4), tetrafunctional epoxy, polyphenylene ether, epoxy/polyphenylene oxide, bismaleimide triazine (BT), thermount, cyanate ester, polyimide and liquid crystal polymer. The wiring pattern 720 may include copper (Cu) or an alloy containing copper (Cu). For example, the wiring pattern 720 may have a structure in which copper (Cu) or an alloy including copper (Cu) is stacked on a seed layer including copper (Cu), titanium (Ti), titanium tungsten (TiW), titanium nitride (TiN), tantalum (Ta), tantalum nitride (TaN), chromium (Cr), Cu/Ti, in which copper is stacked on titanium, or Cu/TiW, in which copper is stacked on titanium tungsten, but is not limited thereto. In some embodiments, the via structure 320 may include electrolytically deposited (ED) copper foil, rolled-annealed (RA) copper foil, stainless steel foil, aluminum foil, ultra-thin copper foils, sputtered copper, copper alloys, etc. In FIG. 10, the package substrate 700 is shown as including a first-layer base insulating layer 710, but this is an example and is not limited thereto. For example, the package substrate 700 may include two or more base insulating layers 710 stacked, and may further include a conductive pattern between each of the two or more base insulating layers 710.

In some embodiments, the package substrate 700 may include a solder resist layer 730 disposed on the upper and lower surfaces of the package substrate 700. The solder resist layer 730 may include a lower surface solder resist layer 732 disposed on the lower surface of the package substrate 700 and an upper surface solder resist layer 734 disposed on the upper surface of the package substrate 700. At least a portion of the plurality of lower surface conductive patterns 722 among a plurality of wiring patterns 720 may be exposed to the lower surface of the package substrate 700 without being covered by the lower surface solder resist layer 732, and at least a portion of the plurality of upper surface conductive patterns 724 among the plurality of wiring patterns 720 may be exposed to the upper surface of the package substrate 700 without being covered by the upper surface solder resist layer 734.

A plurality of package connection terminals 950 may be attached to the plurality of lower surface conductive patterns 722 and a plurality of bonding wires 830 may be connected to the plurality of upper surface conductive patterns 724.

In some embodiments, the upper package UP may further include a package molding layer 890 surrounding the auxiliary semiconductor chip 800 and the plurality of bonding wires 830 on the package substrate 700. For example, the package molding layer 890 may be a molding member containing epoxy mold compound (EMC).

In FIG. 10, the semiconductor package 1000 is shown as including the semiconductor package 1 shown in FIG. 1 as the lower package LP, but inventive concepts are not limited thereto. For example, the semiconductor package 1000 may include the semiconductor package 1a shown in FIG. 3, the semiconductor package 1b shown in FIG. 4, the semiconductor package 1c shown in FIG. 5, or the semiconductor package 1d shown in FIG. 6 as the lower package LP.

Referring to FIG. 11, a semiconductor package 2000 may be a package-on-package that includes a lower package LPa and an upper package UP attached to the lower package LPa. The lower package LPa may be the semiconductor package 2 shown in FIG. 7. The lower package LP includes a first wiring structure 200a, at least one semiconductor chip 100 on the first wiring structure 200a, an expanded layer surrounding the at least one semiconductor chip 100, a ceramic shield layer on the expanded layer 300, and a second wiring structure 400 on the ceramic shield layer 350. An upper package UP may be attached to the second wiring structure 400.

In FIG. 11, the semiconductor package 2000 is shown as including the semiconductor package 2 shown in FIG. 7 as the lower package LPa, but inventive concepts are not limited thereto. For example, the semiconductor package 2000 may include the semiconductor package 2a shown in FIG. 9 as the lower package LPa.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A semiconductor package comprising:
a first wiring structure including a plurality of first redistribution patterns and a plurality of first redistribution insulating layers surrounding the plurality of first redistribution patterns;
a second wiring structure on the first wiring structure, the second wiring structure including a plurality of second redistribution patterns and a plurality of second redistribution insulating layers surrounding the plurality of second redistribution patterns;
a semiconductor chip between the first wiring structure and the second wiring structure;
an expanded layer including a plurality of connection structures electrically connecting the first wiring structure and the second wiring structure to each other and an encapsulant surrounding the plurality of connection structures and the semiconductor chip;
a ceramic shield layer between the expanded layer and the second wiring structure; and
a plurality of via structures penetrating the ceramic shield layer and electrically connecting the plurality of connection structures and the plurality of second redistribution patterns to each other.

2. The semiconductor package of claim 1, wherein a lower surface of the ceramic shield layer is a flat surface extending along a same vertical level.

3. The semiconductor package of claim 1, wherein
an upper surface of the encapsulant and uppermost surfaces of the plurality of connection structures are coplanar with each other.

4. The semiconductor package of claim 1, wherein
the plurality of via structures extend into the plurality of connection structures, and
lower surfaces of the plurality of via structures are at a lower level than a lower surface of the ceramic shield layer.

5. The semiconductor package of claim 1, wherein
the plurality of via structures are in contact with upper surfaces of the plurality of connection structures and have a lower surface located at a same level as a lower surface of the ceramic shield layer.

6. The semiconductor package of claim 1, wherein an upper surface of the ceramic shield layer is a flat surface extending along a same vertical level.

7. The semiconductor package of claim 6, wherein
each of the plurality of via structures includes a pad pattern portion on the upper surface of the ceramic shield layer and a through via portion penetrating the ceramic shield layer from the pad pattern portion, and
the pad pattern portion is connected to and in contact with a corresponding one of the plurality of connection structures.

8. The semiconductor package of claim 7, wherein
in each of the plurality of via structures, the pad pattern portion and the through via portion are integrated with each other.

9. The semiconductor package of claim 1, wherein
a thickness of the ceramic shield layer is greater than a thickness of each of the plurality of second redistribution insulating layers.

10. The semiconductor package of claim 1, wherein
the encapsulant covers a side surface of the semiconductor chip and an upper surface of the semiconductor chip, and
a thickness of the ceramic shield layer is smaller than a thickness of a portion of the encapsulant covering the upper surface of the semiconductor chip.

11. A semiconductor package comprising:
a first wiring structure including a plurality of first redistribution insulating layers and a plurality of first redistribution patterns,
the plurality of first redistribution patterns including a plurality of first redistribution line patterns and a plurality of first redistribution vias,
the plurality of first redistribution line patterns on at least one of upper surfaces and lower surfaces of the plurality of first redistribution insulating layers, and
the plurality of first redistribution vias being connected to the plurality of first redistribution line patterns and penetrating at least one of the plurality of first redistribution insulating layers;
a plurality of connection structures on the first wiring structure and connected to some first redistribution patterns among the plurality of first redistribution patterns;
a semiconductor chip spaced apart from the plurality of connection structures in a horizontal direction on the first wiring structure and electrically connected to other first redistribution patterns among the plurality of first redistribution patterns;
an encapsulant surrounding the plurality of connection structures and the semiconductor chip on the first wiring structure;
a ceramic shield layer covering the encapsulant and having a plurality of through holes;
a plurality of via structures filing the plurality of through holes of the ceramic shield layer, the plurality of via structures being connected to and in contact with the plurality of connection structures; and
a second wiring structure on the ceramic shield layer,
the second wiring structure including a plurality of second redistribution insulating layers and a plurality of second redistribution patterns,
the plurality of second redistribution patterns including a plurality of second redistribution line patterns and a plurality of second redistribution vias,
the plurality of second redistribution line patterns on at least one of upper surfaces and lower surfaces of the plurality of second redistribution insulating layers,
the plurality of second redistribution vias being connected to the plurality of second redistribution line patterns and penetrating at least one of the plurality of second redistribution insulating layers, wherein
lowest second redistribution vias among the plurality of second redistribution vias are connected to and in contact with the plurality of pad patterns.

12. The semiconductor package of claim 11, wherein
a lower surface of the ceramic shield layer, an upper surface of the encapsulant, and uppermost surfaces of the plurality of connection structures are located at a same vertical level.

13. The semiconductor package of claim 12, wherein the ceramic shield layer has a constant thickness and covers the encapsulant.

14. The semiconductor package of claim 12, wherein
the plurality of via structures include a plurality of pad pattern portions on an upper surface of the ceramic shield layer and a plurality of through via portions penetrating the ceramic shield layer from the plurality of pad pattern portions,
the plurality of through via portions are connected to and in contact with corresponding connection structures among the plurality of connection structures, and
in the plurality of via structures, the plurality of pad pattern portions and the plurality of through via portions are correspondingly connected to each other and form integrated bodies.

15. The semiconductor package of claim 14, wherein
the plurality of through via portions extend into the plurality of connection structures in which the plurality of through via portions are connected in contact with.

16. The semiconductor package of claim 14, wherein
the plurality of second redistribution vias each have a tapered shape whose horizontal width increases as a distance from the semiconductor chip increases, and
an acute angle formed between a side surface of each of the plurality of through vias and a horizontal plane has a value greater than an acute angle formed between a side surface of each of the plurality of second redistribution vias and the horizontal plane.

17. The semiconductor package of claim 11, wherein
a portion of the encapsulant covering an upper surface of the semiconductor chip is thicker than the ceramic shield layer, and
the ceramic shield layer is thicker than each of the plurality of second redistribution insulating layers.

18. A semiconductor package comprising:
a lower package including a first wiring structure, a second wiring structure on the first wiring structure, a semiconductor chip between the first wiring structure and the second wiring structure, a plurality of connection structures electrically connecting the first wiring structure and the second wiring structure to each other, an encapsulant covering a side surface of the semiconductor chip and an upper surface of the semiconductor chip, a ceramic shield layer between the encapsulant and the second wiring structure, and a plurality of via structures penetrating the ceramic shield layer,
the first wiring structure including a plurality of first redistribution patterns and a plurality of first redistribution insulating layers surrounding the plurality of first redistribution patterns,
the second wiring structure including a plurality of second redistribution patterns and a plurality of second redistribution insulating layers surrounding the plurality of second redistribution patterns,
the plurality of connection structures being spaced apart from the semiconductor chip in a horizontal direction and disposed around the semiconductor chip,
the encapsulant surrounding the plurality of connection structures, and
the plurality of via structures electrically connecting the plurality of connection structures and the plurality of second redistribution patterns to each other;
an upper package attached to the lower package and including an auxiliary semiconductor chip; and
a plurality of package connection terminals between the lower package and the upper package, the plurality of package connection terminals electrically connecting the lower package and the upper package to each other, wherein
an upper surface of the encapsulant and an uppermost surface of the plurality of connection structures are located at a same vertical level and form a coplanar surface, and
a lower surface of the ceramic shield layer is a flat surface in contact with the upper surface of the encapsulant and the uppermost surface of the plurality of connection structures.

19. The semiconductor package of claim 18, wherein a thickness of the ceramic shield layer is 5 μm to 10 μm.

20. The semiconductor package of claim 18, wherein the ceramic shield layer comprises Ti₃CN.
